(19) United States
(12) Patent Application Publication
(10) Pub. No.: US 2014/0299889 A1
(43) Pub. Date: Oct. 9, 2014

(54) SEMICONDUCTOR DEVICES

(71) Applicant: Samsung Electronics Co., Ltd., Suwon-Si (KR)

(72) Inventors: Choong-Rae CHO, Suwon-si (KR); Dae-Keun KANG, Incheon (KR); Eun-Sung KIM, Seoul (KR); Chul-Ho SHIN, Yongin-si (KR); Han-Geun YU, Seoul (KR)

(73) Assignee: Samsung Electronics Co., Ltd., Suwon-Si (KR)

(21) Appl. No.: 14/247,570

(22) Filed: Apr. 8, 2014

(30) Foreign Application Priority Data
Apr. 8, 2013 (KR) 10-2013-0038048

(51) Int. Cl. H01L 27/092

(52) U.S. Cl. CPC H01L 27/092
USPC 257/77; 257/369

(57) ABSTRACT

A semiconductor device includes a first gate structure on a first region of a substrate and a second gate structure on a second region of the substrate, a first impurity region on an upper portion of the substrate adjacent to the first gate structure and a second impurity region on an upper portion of the substrate adjacent to the second gate structure, a first metal silicide layer on the first impurity region, a Fermi level pinning layer on the second impurity region, a second metal silicide layer on the Fermi level pinning layer, and a first contact plug on the first metal silicide layer and a second contact plug on the second metal silicide layer. The Fermi level pinning layer pins a Fermi level of the second metal silicide layer to a given energy level.

### CROSS-REFERENCE TO RELATED APPLICATION

This application claims priority under 35 USC §119 to Korean Patent Application No. 10-2013-0038048, filed on Apr. 8, 2013 in the Korean Intellectual Property Office (KIPO), the contents of which are herein incorporated by reference in their entirety.

### BACKGROUND

1. Field

Some example embodiments relate to semiconductor devices and methods of manufacturing the same. Other example embodiments relate to semiconductor devices having CMOS transistors and contact plugs electrically connected thereto, and methods of manufacturing the same.

2. Description of the Related Art

In a complementary metal oxide semiconductor (CMOS) transistor including a negative-channel metal oxide semiconductor (NMOS) transistor and a positive-channel metal oxide semiconductor (PMOS) transistor, methods of reducing a contact resistance between source/drain regions including a semiconductor material and a contact plug including a metal have been studied. For example, there is a method of increasing a concentration of impurities of the source/drain regions, however, the method may have a limitation. Alternatively, there is a method of forming a metal silicide layer between the contact plug and the source/drain regions, however, complicated processes are needed in order to reduce the contact resistance to a desired degree.

### SUMMARY

Some example embodiments provide a semiconductor device having a relatively low contact resistance between a CMOS transistor and a contact plug.

Other example embodiments provide a method of manufacturing a semiconductor device having a relatively low contact resistance between a CMOS transistor and a contact plug.

According to an example embodiment, a semiconductor device includes a first gate structure on a first region of a substrate and a second gate structure on a second region of the substrate, a first impurity region on an upper portion of the substrate adjacent to the first gate structure and a second impurity region on an upper portion of the substrate adjacent to the second gate structure, a first metal silicide layer on the first impurity region, a Fermi level pinning layer on the second impurity region, a second metal silicide layer on the Fermi level pinning layer, the Fermi level pinning layer pinning a Fermi level of the second metal silicide layer to a given energy level, and a first contact plug on the first metal silicide layer and a second contact plug on the second metal silicide layer. The Fermi level pinning layer pins a Fermi level of the second metal silicide layer to a given energy level.

In an example embodiment, the first impurity region may include n-type impurities, and the second impurity region may include p-type impurities.

In an example embodiment, the Fermi level pinning layer may pin the Fermi level of the second metal silicide layer to a level adjacent to an edge of a valence band of the Fermi level pinning layer at a surface contacting the second metal silicide layer.

In an example embodiment, the Fermi level pinning layer may include a germanium layer.

In an example embodiment, the first and second metal silicide layers may include a rare earth metal.

In an example embodiment, the second impurity region may include a silicon-germanium layer, and the silicon-germanium layer may have a germanium concentration gradient that increases from a bottom portion to a top portion thereof.

In an example embodiment, the second impurity region may include silicon.

In an example embodiment, the first impurity region may include silicon carbide.

In an example embodiment, the first impurity region may include p-type impurities, and the second impurity region may include n-type impurities.

In an example embodiment, the Fermi level pinning layer may pin the Fermi level of the second metal silicide layer to a level adjacent to an edge of a conduction band of the Fermi level pinning layer at a surface contacting the second metal silicide layer.

In an example embodiment, the first and second metal silicide layers may include a noble metal.

In an example embodiment, the first and second contact plugs may include a metal.

According to another example embodiment, a method of manufacturing a semiconductor device includes forming a first gate structure on a first region of a substrate and a second gate structure on a second region of the substrate, forming a second impurity region on a portion of the substrate adjacent to the second gate structure, forming a Fermi level pinning layer on the second impurity region, forming a first impurity region on a portion of the substrate adjacent to the first gate structure, forming a first metal silicide layer on the first impurity region, forming a second metal silicide layer on the Fermi level pinning layer, the Fermi level pinning layer pinning a Fermi level of the second metal silicide layer to a given energy level, and forming a first contact plug on the first metal silicide layer and a second contact plug on the second metal silicide layer. The Fermi level pinning layer pins a Fermi level of the second metal silicide layer to a given energy level.

In another example embodiment, when the second impurity region is formed, a silicon-germanium layer doped with p-type impurities may be formed. When the Fermi level pinning layer is formed, a germanium layer may be formed.

In another example embodiment, the second impurity region and the Fermi level pinning layer may be formed in-situ.

According to yet another example embodiment, a semiconductor device includes a first gate structure on a first region of a substrate and a second gate structure on a second region of the substrate, a first impurity region adjacent to the first gate structure and a second impurity region adjacent to the second gate structure, a first metal silicide layer on the first impurity region and a second metal silicide layer on the second impurity region, the first and second metal silicide layers including a same metal, and a Fermi level pinning layer between the second impurity region and the second metal silicide layer, the Fermi level pinning layer pinning a Fermi level of the second metal silicide layer to a given energy level.

In yet another example embodiment, the first impurity region may include n-type impurities, and the second impurity region may include p-type impurities.

In yet another example embodiment, the Fermi level pinning layer may pin a Fermi level of the second metal silicide layer to a level adjacent to an edge of a valence band of the Fermi level pinning layer at a surface contacting the second metal silicide layer.

In yet another example embodiment, the Fermi level pinning layer may include a germanium layer.

In yet another example embodiment, the first and second metal silicide layers may include a rare earth metal.

In yet another example embodiment, the first impurity region may include p-type impurities, and the second impurity region may include n-type impurities.

In yet another example embodiment, the Fermi level pinning layer may pin a Fermi level of the second metal silicide layer to a level adjacent to an edge of a conduction band of the Fermi level pinning layer at a surface contacting the second metal silicide layer.

In yet another example embodiment, the first and second metal silicide layers may include a noble metal.

According to example embodiments, a metal silicide layer including a metal having a relatively low work function may be commonly formed on an n-type impurity region and a p-type impurity region, and thus a CMOS transistor may be formed by a simple process and at a relatively low cost. A Schottky barrier between the n-type impurity region and the metal silicide layer is low, and thus a relatively low contact resistance may be realized therebetween. A germanium layer may be formed on the p-type impurity region to pin a Fermi level of the metal silicide layer to a level adjacent to an edge of a valence band, and thus a Schottky barrier between the p-type impurity region and the metal silicide layer may be reduced to also realize a relatively low contact resistance therebetween.

### BRIEF DESCRIPTION OF THE DRAWINGS

Example embodiments will be more clearly understood from the following detailed description taken in conjunction with the accompanying drawings. FIGS. 1 to 50 represent non-limiting, example embodiments as described herein.

FIG. 1 is a cross-sectional view illustrating a semiconductor device in accordance with an example embodiment;

FIG. 2 is an energy band diagram when a metal layer and an n-type semiconductor layer doped with n-type impurities contact each other;

FIG. 3 is an energy band diagram when a metal layer and a p-type semiconductor layer doped with p-type impurities contact each other;

FIG. 4 is an energy band diagram illustrating a relationship between a Fermi level and a Schottky barrier when a metal layer and a semiconductor layer contact each other, and

FIG. 5 is an energy band diagram illustrating a relationship between a Fermi level and a Schottky barrier when a metal layer having a relatively low work function and a silicon layer contact each other;

FIG. 6 is an energy band diagram illustrating a relationship between a Fermi level and a Schottky barrier when a metal layer contacts a germanium layer on a silicon layer;

FIG. 7 is an energy band diagram illustrating a movement of charges between a metal layer and a germanium layer when the germanium layer and a silicon-germanium layer are sequentially formed on a silicon layer;

FIGS. 8 to 17 are cross-sectional views illustrating stages of a method of manufacturing a semiconductor device in accordance with an example embodiment;

FIG. 18 is a cross-sectional view illustrating a semiconductor device in accordance with another example embodiment;

FIGS. 19 to 21 are cross-sectional views illustrating stages of a method of manufacturing a semiconductor device in accordance with another example embodiment;

FIG. 22 is a cross-sectional view illustrating a semiconductor device in accordance with another example embodiment;

FIG. 23 is a cross-sectional view illustrating a semiconductor device in accordance with another example embodiment;

FIGS. 24 to 27 are cross-sectional views illustrating stages of a method of manufacturing a semiconductor device in accordance with another example embodiment;

FIG. 28 is a cross-sectional view illustrating a semiconductor device in accordance with another example embodiment;

FIG. 29 is a semiconductor device in accordance with another example embodiment;

FIGS. 30 to 38 are cross-sectional views illustrating stages of a method of manufacturing a semiconductor device in accordance with another example embodiment;

FIG. 39 is a semiconductor device in accordance with another example embodiment; and

FIGS. 40 to 50 are cross-sectional views illustrating stages of a method of manufacturing a semiconductor device in accordance with another example embodiment.

### DETAILED DESCRIPTION

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a semiconductor device in accordance with an example embodiment.

Referring to FIG. 1, the semiconductor device may include a first gate structure 152, a first impurity region 250, a first metal silicide layer 272 and a first contact plug 292 on a substrate 100 in a first region I, and a second gate structure 154, a second impurity region 190, a Fermi level pinning layer 200, a second metal silicide layer 274 and a second contact plug 294 on the substrate 100 in a second region II. The semiconductor device may further include first and second gate spacers 162 and 164 on sidewalls of the first and second gate structures 152 and 154, respectively.

The substrate 100 may be a semiconductor substrate, or a silicon-on-insulator (SOI) substrate. The substrate 100 may be divided into the first region I and the second region II. The first region I may be an NMOS region in which NMOS transistors may be formed, and the second region II may be a PMOS region in which PMOS transistors may be formed. The substrate 100 may further include a well (not shown) including n-type impurities or p-type impurities.

An isolation layer 110 may be formed on the substrate 100 to divide the substrate 100 into an active region and a field region. The isolation layer 110 may include an insulating material, e.g., silicon oxide.

The first gate structure 152 may include a first gate insulation layer pattern 122, a first gate electrode 132 and a first gate mask 142 sequentially stacked on the substrate 100. The first gate insulation layer pattern 122 may include, e.g., silicon oxide and/or a metal oxide, the first gate electrode 132 may include, e.g., doped polysilicon, a metal, a metal nitride, a metal silicide, etc., and the first gate mask 142 may include, e.g., silicon nitride. The second gate structure 154 may include a second gate insulation layer pattern 124, a second gate electrode 134 and a second gate mask 144 sequentially stacked on the substrate 100. The second gate insulation layer pattern 124, the second gate electrode 134 and the second gate mask 144 may include substantially the same materials as those of the first gate insulation layer pattern 122, the first gate electrode 132 and the first gate mask 142, respectively.

The first and second gate spacers 162 and 164 may include silicon nitride and/or silicon oxide.

The first impurity region 250 may be formed on a portion of the substrate 100 adjacent to the first gate structure 152. In another example embodiment, two first impurity regions 250 may be formed on portions of the substrate 100 adjacent to the sidewalls of the first gate structure 152. For example, the first impurity region 250 may include n-type impurities, e.g., phosphorus, arsenic, etc. In another example embodiment, the first impurity region 250 may include a single crystalline silicon carbide layer doped with n-type impurities.

The first gate structure 152 together with the first impurity regions 250 may form an NMOS transistor. As each first impurity region 250 includes a silicon carbide layer, a tensile stress may be applied to a first channel between the first impurity regions 250 under the first gate structure 152, so that a mobility of electrons in the first channel may be enhanced.

The second impurity region 190 may be formed on a portion of the substrate 100 adjacent to the second gate structure 154. In another example embodiment, two second impurity regions 190 may be formed on portions of the substrate 100 adjacent to the sidewalls of the second gate structure 154. For example, the second impurity region 190 may include p-type impurities, e.g., boron, gallium, etc. In another example embodiment, the second impurity region 190 may include a single crystalline silicon-germanium layer doped with p-type impurities.

The second gate structure 154 together with the second impurity regions 190 may form a PMOS transistor. As each second impurity region 190 includes a silicon-germanium layer, a compressive stress may be applied to a second channel between the second impurity regions 190 under the second gate structure 154, so that a mobility of holes in the second channel may be enhanced.

In another example embodiment, the silicon-germanium layer may have a germanium concentration gradient increasing from a bottom portion to a top portion thereof. The germanium concentration may increase continuously or discontinuously, e.g., in a shape of stairs.

The Fermi level pinning layer 200 may be formed on the second impurity region 190. The Fermi level pinning layer 200 may include a material that may stick or pin a Fermi level of a metal layer or a metal silicide layer to a given energy level when it contacts the metal layer or the metal nitride layer. In another example embodiment, the Fermi level pinning layer 200 may include a material that may pin a Fermi level of a metal layer or a metal nitride layer contacting the Fermi level pinning layer 200 to a level near an edge of a valence band at an interface therebetween, e.g., to a level within about 0.1 eV range from the edge of the valence band.

In another example embodiment, the Fermi level pinning layer 200 may include a germanium layer. In this case, the germanium layer may pin a Fermi level of the second metal silicide layer 274 contacting the germanium layer to a level higher than an edge of a valence band of the germanium layer at an interface therebetween by about 0.09 eV. In an example embodiment, the germanium layer may be doped with p-type impurities, e.g., gallium.

The first and second metal silicide layers 272 and 274 may be formed on the first impurity region 250 and the Fermi level pinning layer 200, respectively. In another example embodiment, the first and second metal silicide layers 272 and 274 may include a metal having a relatively low work function, e.g., a rare earth metal such as lanthanum, cerium, yttrium, etc.

The first and second gate structures 152 and 154, the first and second gate spacers 162 and 164, the first and second impurity regions 250 and 190, the Fermi level pinning layer 200, and the first and second metal silicide layers 272 and 274 may be covered by an insulating interlayer 280, and the first and second contact plugs 292 and 294 may be formed through the insulating interlayer 280 to contact top surfaces of the first and second metal silicide layers 272 and 274, respectively. The insulating interlayer 280 may include an insulating material, e.g., silicon oxide, and the first and second contact plugs 292 and 294 may include, e.g., a metal, a metal nitride, a metal silicide, etc.

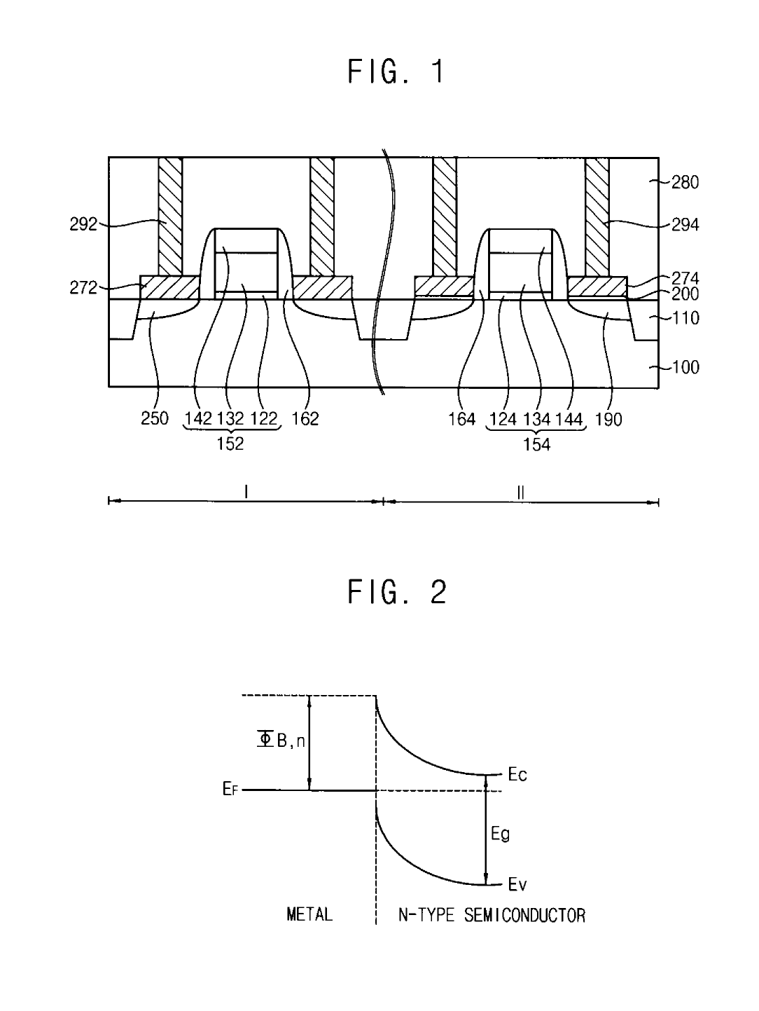

In another example embodiment, the semiconductor device may have a relatively low first contact resistance between the first impurity region 250 and the first contact plug 292, and a relatively low second contact resistance between the second impurity region 190 and the second contact plug 294 through the first and second metal silicide layers 272 and 274 and the Fermi level pinning layer 200, which may be illustrated later with reference to FIGS. 2 to 7.

When a metal layer and a semiconductor layer contact each other, a Schottky barrier may occur to restrict the movement of electrons therebetween, so that a contact resistance between the metal layer and the semiconductor layer may be increased.

FIG. 2 is an energy band diagram when a metal layer and an n-type semiconductor layer doped with n-type impurities contact each other.

Referring to FIG. 2, an energy band gap Eg may exist between an edge Ec of a conduction band and an edge Ev of a valence band in the n-type semiconductor layer, and a difference between the edge Ec of the conduction band of the n-type semiconductor layer and a Fermi level E_{F} of the metal layer at an interface between the n-type semiconductor layer and the metal layer may be referred to as an n-type Schottky barrier Φ_{B,n}. A difference between an edge Ec of a conduction band and the Fermi level Ef in the metal layer may be identical to a work function of the metal layer, and thus, when a metal layer having a relatively low work function and an n-type semiconductor layer contact each other, the n-type Schottky barrier Φ_{B,n} therebetween may be low, which means that the movement of electrons is easy, so that the contact resistance between the metal layer and the n-type semiconductor layer may be low.

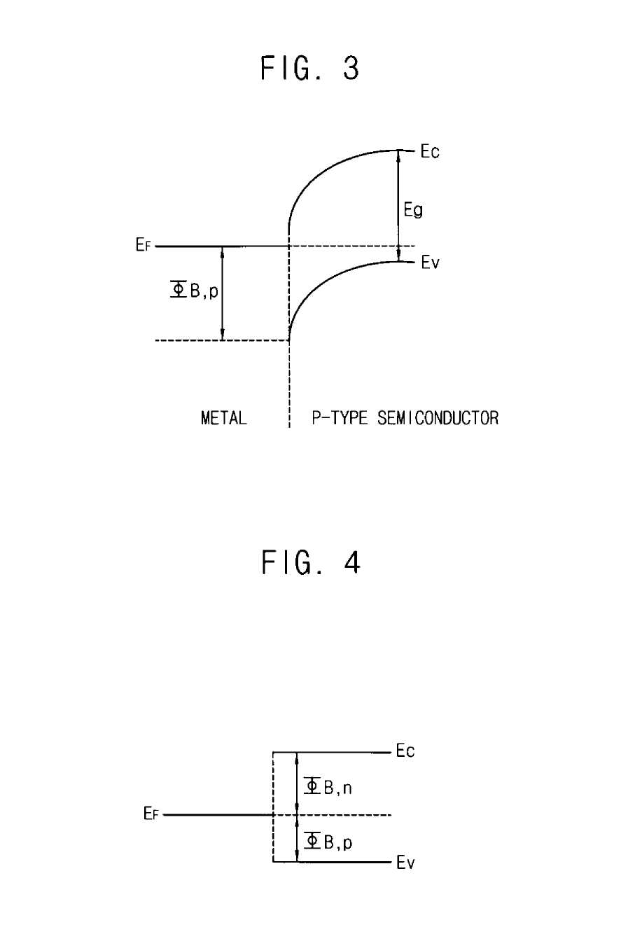

FIG. 3 is an energy band diagram when a metal layer and a p-type semiconductor layer doped with p-type impurities contact each other.

Referring to FIG. 3, an energy band gap Eg may exist between an edge Ec of a conduction band and an edge Ev of a valence band in the p-type semiconductor layer, and a difference between a Fermi level E_{F} of the metal layer and the edge Ev of the valence band of the p-type semiconductor layer at an interface between the metal layer and the p-type semiconductor layer may be referred to as a p-type Schottky barrier Φ_{B,p}. When a metal layer having a relatively low work function and a p-type semiconductor layer contact each other, the p-type Schottky barrier φ_{B,p} therebetween may be high, which means that the movement of holes is not easy, so that the contact resistance between the metal layer and the p-type semiconductor layer may be high.

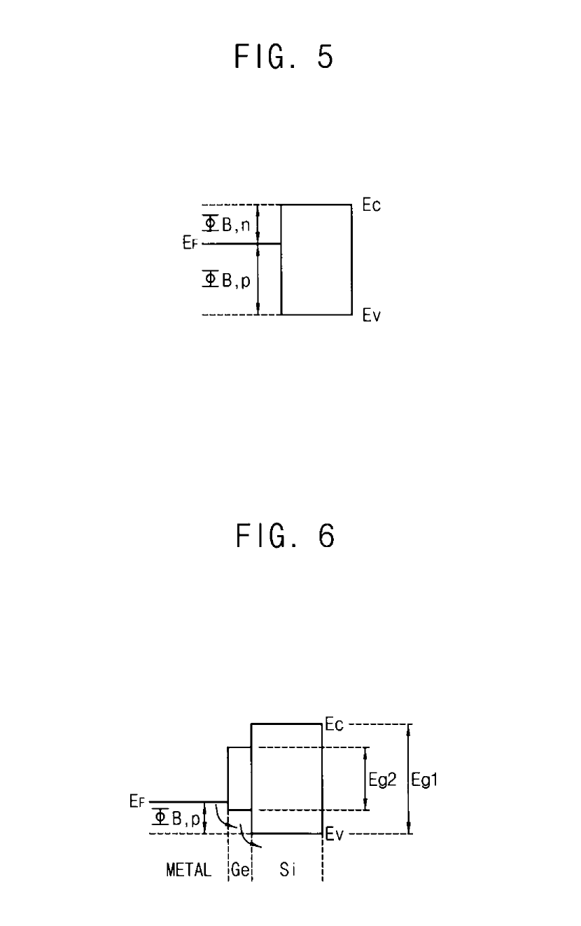

FIG. 4 is an energy band diagram illustrating a relationship between a Fermi level and a Schottky barrier when a metal layer and a semiconductor layer contact each other, and FIG. 5 is an energy band diagram illustrating a relationship between a Fermi level and a Schottky barrier when a metal layer having a relatively low work function and a silicon layer contact each other.

Referring to FIG. 4, when a Fermi level E_{F} of the metal layer is relatively high, i.e., when a work function of the metal layer is relatively low, an n-type Schottky barrier Φ_{B,n}, which is a difference between an edge Ec of a conduction band of an n-type semiconductor layer and the Fermi level E_{F} of the metal layer, may be low, while a p-type Schottky barrier Φ_{B,p}, which is a difference between the Fermi level E_{F} of the metal layer and an edge Ev of a valence band of a p-type semiconductor layer, may be high. Thus, when a metal layer having a relatively low work function contacts an n-type semiconductor layer and a p-type semiconductor layer, a contact resistance between the metal layer and the n-type semiconductor layer may be low, while a contact resistance between the metal layer and the p-type semiconductor layer may be high. On the contrary, when a metal layer having a high work function contacts an n-type semiconductor layer and a p-type semiconductor layer, a contact resistance between the metal layer and the n-type semiconductor layer may be high, while a contact resistance between the metal layer and the p-type semiconductor layer may be low.

Thus, when a metal layer contacts both n-type and p-type semiconductor layers, it may be difficult both of a contact resistance between the metal layer and the n-type semiconductor layer and a contact resistance between the metal layer and the p-type semiconductor layer may be low.

Referring to FIG. 5, as the metal layer having a relatively low work function contacts the silicon layer doped with n-type impurities, an n-type Schottky barrier Φ_{B,n} may be low, while a p-type Schottky barrier Φ_{B,p} may be high. Thus, when contact plugs are formed on a silicon layer doped with n-type impurities and a silicon layer doped with p-type impurities, respectively, in order to reduce contact resistances between the contact plugs and the silicon layer, a metal silicide layer may be formed, however, forming the metal silicide layer to include a metal having a relatively low work function on the silicon layer doped with the n-type impurities and to include a metal having a high work function on the silicon layer doped with the p-type impurities is needed, which may complicate processes and cause an increase of cost.

FIG. 6 is an energy band diagram illustrating a relationship between a Fermi level and a Schottky barrier when a metal layer contacts a germanium layer on a silicon layer. The metal layer may include a metal substantially the same as that of the metal layer illustrated with reference to FIG. 5, i.e., the metal layer may have a work function substantially the same as that of the metal layer of FIG. 5.

Referring to FIG. 6, as the metal layer contacts the germanium layer, a Fermi level pinning in which a Fermi level E_{F} may be pinned to a given energy level may occur.

That is, the germanium layer may have characteristics in that a charge neutrality level (CNL) is adjacent to an edge Ev of a valence band and pin a Fermi level E_{F} of a metal layer contacting the germanium layer to the CNL. Thus, even though a metal layer or a metal silicide layer includes a metal having a relatively low work function, when it contacts a germanium layer, a Fermi level E_{F} of the metal layer or the metal silicide layer may be pinned adjacent to the edge Ev of the valence band of the germanium layer so as to have a relatively low p-type Schottky barrier Φ_{B,p}.

When a metal silicide layer including a metal having a relatively low work function is formed on both of a silicon layer doped with n-type impurities and a germanium layer that is formed on a silicon layer doped with p-type impurities, not only an n-type Schottky barrier Φ_{B,n} between the metal silicide layer and the silicon layer doped with n-type impurities but also a p-type Schottky barrier Φ_{B,p} between the metal silicide layer and the germanium layer and further between the metal silicide layer and the silicon layer doped with p-type impurities may be low, and thus metal silicide layers including different metals from each other may not be formed in order to have relatively low contact resistances therebetween.

As a result, in the semiconductor in accordance with example embodiments, a metal silicide layer including a metal having a relatively low work function, e.g., a rare earth metal serving as the first metal silicide layer 272 may be formed on a silicon carbide layer doped with n-type impurities serving as the first impurity region 250, so that the first contact resistance may be low. Additionally, even though a metal silicide layer including a metal having a relatively low work function, e.g., a rare earth metal, which may be substantially the same as the metal silicide layer on the first impurity region 250, serving as the second metal silicide layer 274 may be formed on a silicon-germanium layer doped with p-type impurities serving as the second impurity region 190, a germanium layer serving as the Fermi level pinning layer 200 may be formed between the second metal silicide layer 274 and the second impurity region 190, so that the second contact resistance may be also low.

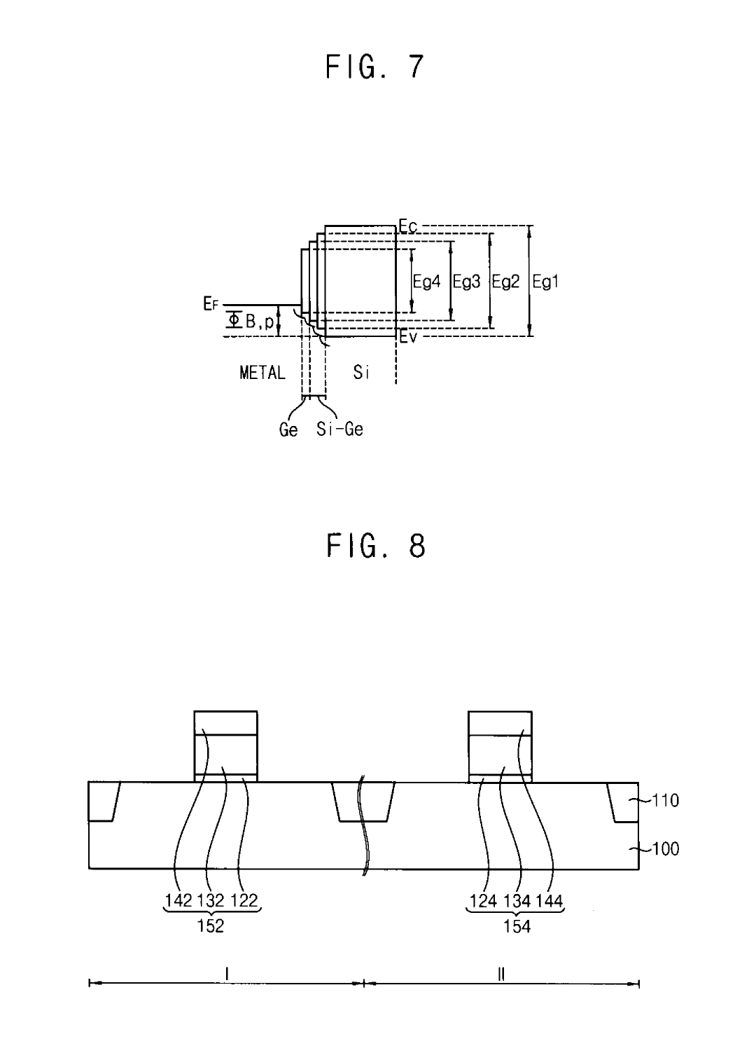

FIG. 7 is an energy band diagram illustrating a movement of charges between a metal layer and a germanium layer when the germanium layer and a silicon-germanium layer are sequentially formed on a silicon layer.

Silicon and germanium may have energy band gaps of about 1.1 eV and about 0.7 eV, respectively, and a silicon-germanium layer including both silicon and germanium may have an energy band gap between the above energy band gaps. As a germanium concentration of the silicon-germanium layer increases, the energy band gap thereof may decrease.

Thus, when a plurality of silicon-germanium layers having germanium concentrations higher in this order is sequentially formed, these may have discontinuous energy band gaps Eg3 and Eg4 in a shape of stairs as shown in FIG. 7.

When a metal layer contacts the germanium layer, even though the total p-type Schottky barrier Φ_{B,p} between the metal layer and the silicon layer may be substantially the same as that of FIG. 6, the Schottky barrier Φ_{B,p} is divided into plural numbers each of which may have a relatively low value, and thus the movement of charges, i.e., holes from the metal layer to the silicon layer may be easier. As a result, the contact resistance between the silicon layer and the metal layer may be more reduced by forming the plurality of silicon-germanium layers on the silicon layer.

FIG. 7 shows the plurality of silicon-germanium layers having the energy band gaps Eg3 and Eg4 in the shape of stairs, however, a single silicon-germanium layer having an energy band gap varying continuously may have substantially the same effect. That is, when a silicon-germanium layer having a germanium concentration gradient is formed between a silicon layer and a metal layer, a lower contact resistance may be realized, and in this case, the germanium concentration may vary continuously or discontinuously.

Accordingly, the semiconductor device may have the silicon-germanium layer having the germanium concentration gradient serving as the second impurity region 190, so that the second contact resistance between the second impurity region 190 and the second metal silicide layer 274 may be lower.

Up to now, a method in which the first metal silicide layer 272 having a relatively low work function may be formed on the first impurity region 250 of the NMOS transistor to realize the relatively low first contact resistance therebetween, and the Fermi level pinning layer 200 pinning a Fermi level of a metal layer a level adjacent to an edge of a valence band may be further formed on the second impurity region 190 of the PMOS transistor to realize the relatively low second contact resistance therebetween even though the second metal silicide layer 274 having a relatively low work function like the first metal silicide layer 272 may be formed on the second impurity region 190, has been illustrated. However, the present inventive concepts may be applied to layers of the opposite conduction type.

That is, a second metal silicide layer having a high work function may be formed on a second impurity region of a PMOS transistor to realize a relatively low second contact resistance therebetween, and a Fermi level pinning layer pinning a Fermi level of a metal layer to a level adjacent to an edge of a conduction band may be further formed on a first impurity region of an NMOS transistor to realize a relatively low first contact resistance therebetween, even though the first metal silicide layer having a high work function like the second metal silicide layer may be formed on the first impurity region.

For the convenience of explanation, hereinafter, only the case in which the Fermi level pinning layer 200 is formed on the second impurity region 190 of the PMOS transistor will be illustrated.

A contact resistance between a semiconductor layer doped with impurities and a metal layer may be inversely proportional a Schottky barrier and proportional to an impurity concentration of the semiconductor layer, and thus impurities may be doped into the Fermi level pinning layer 200 to reduce the contact resistance more. That is, when the germanium layer serves as the Fermi level pinning layer 200, p-type impurities, e.g., gallium may be doped into the germanium layer to reduce the contact resistance more.

FIGS. 8 to 17 are cross-sectional views illustrating stages of a method of manufacturing a semiconductor device in accordance with an example embodiment. This method may be used in manufacturing the semiconductor device of FIG. 1, however, may not be limited thereto.

Referring to FIG. 8, first and second gate structures 152 and 154 may be formed on first and second regions I and II of a substrate 100 having an isolation layer 110 thereon.

In an example embodiment, the isolation layer 110 may be formed by a shallow trench isolation (STI) process. That is, a trench (not shown) may be formed on the substrate 100, an insulation layer may be formed on the substrate 100 to sufficiently fill the trench, and an upper portion of the insulation layer may be planarized until a top surface of the substrate 100 may be exposed to form the isolation layer 110.

In an example embodiment, the first region I may be a region in which NMOS transistors may be formed, and the second region II may be a region in which PMOS transistors may be formed.

The first and second gate structures 152 and 154 may be formed by sequentially forming a gate insulation layer, a gate electrode layer and a gate mask layer on the substrate 100, and patterning the gate mask layer, the gate electrode layer and the gate insulation layer through a photolithography process. Thus, the first gate structure 152 may be formed to include a first gate insulation layer pattern 122, a first gate electrode 132 and a first gate mask 142 sequentially stacked on the substrate 100 in the first region I, and the second gate structure 154 may be formed to include a second gate insulation layer pattern 124, a second gate electrode 134 and a second gate mask 144 sequentially stacked on the substrate 100 in the second region II.

The gate insulation layer may be formed to include, e.g., silicon oxide, a metal oxide, etc., the gate electrode layer may be formed to include, e.g., doped polysilicon, a metal, a metal nitride, a metal silicide, etc., and the gate mask layer may be formed to include, e.g., silicon nitride.

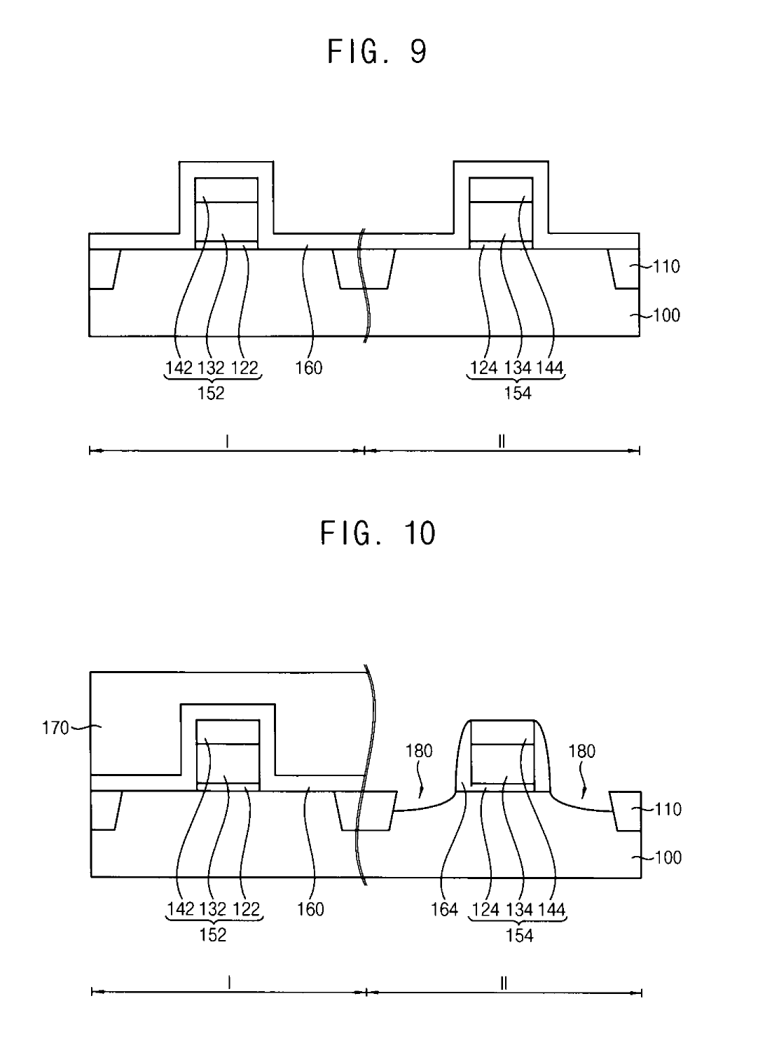

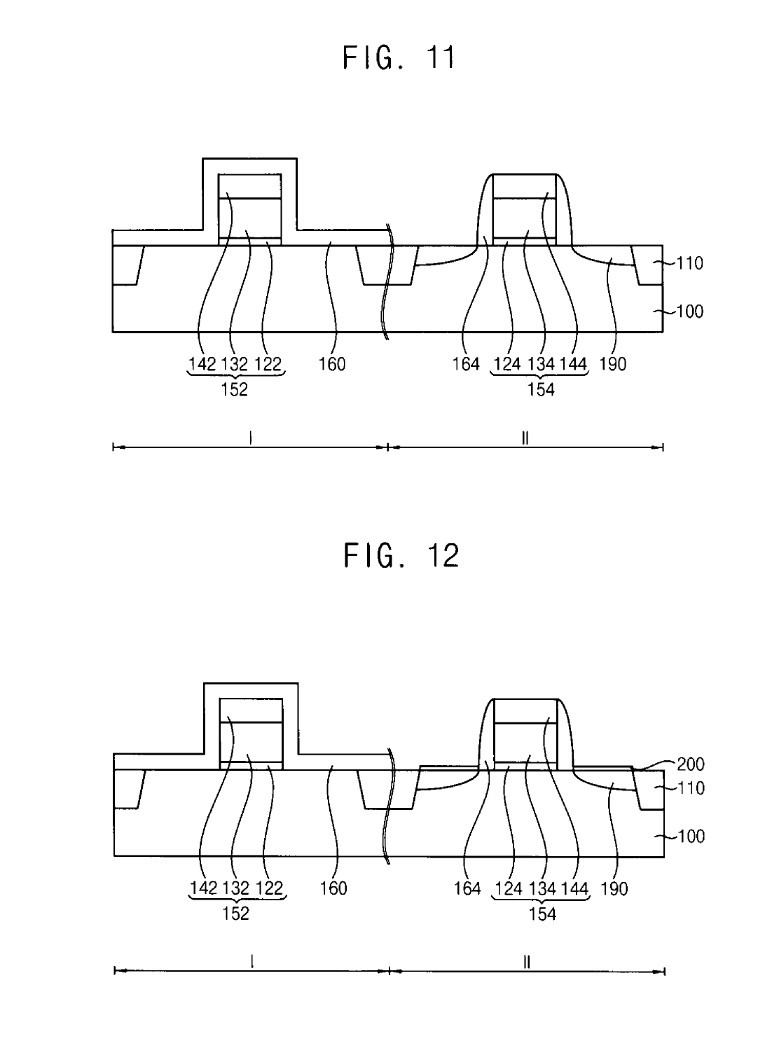

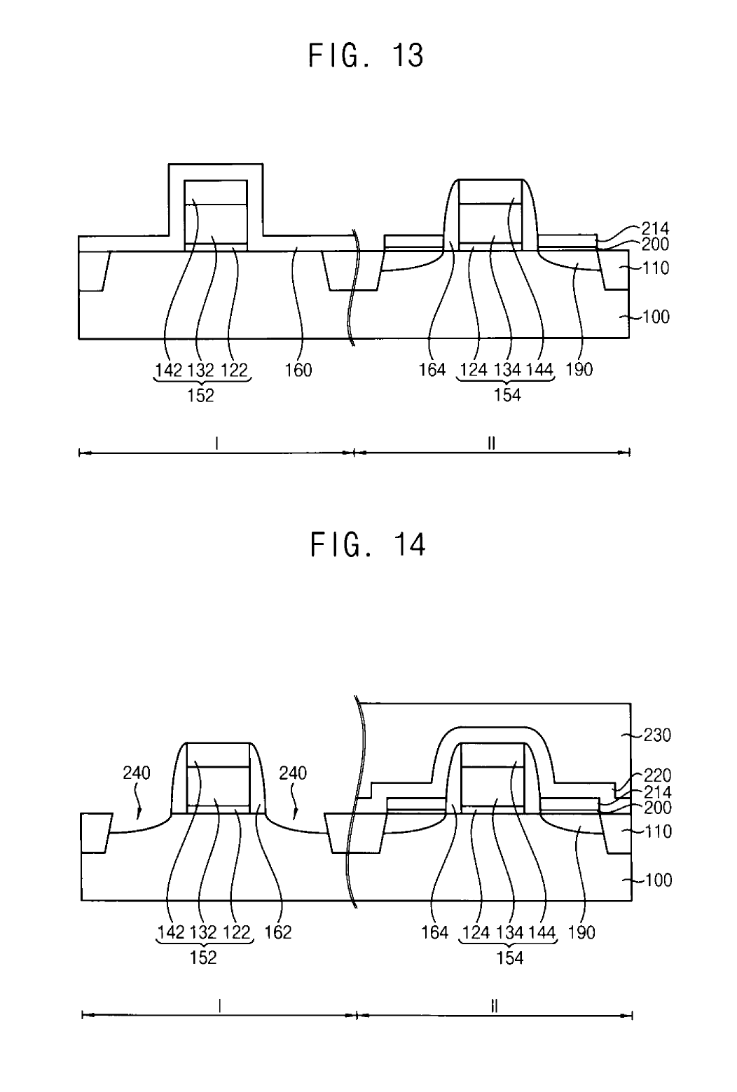

Referring to FIG. 9, a first capping layer 160 may be formed on the substrate 100 to cover the first and second gate structures 152 and 154.

The first capping layer 160 may be formed to include, e.g., silicon nitride and/or silicon oxide.

Referring to FIG. 10, a first mask 170 covering the first region I may be formed on the first capping layer 160, and a portion of the first capping layer 160 in the second region II may be etched using the first mask 170 as an etching mask to expose a top surface of the substrate 100.

In an example embodiment, the etching process may be performed by an anisotropic etching process. Thus, the first capping layer 160 may remain only on a sidewall of the second gate structure 154 in the second region II, and hereinafter, may be referred to as a second gate spacer 164. In the first region I, the first capping layer 160 may still remain on the substrate 100.

An exposed upper portion of the substrate 100 may be removed to form a first recess 180. That is, the first recess 180 may be formed by an etching process using the first mask 170, the second gate structure 154 and the second gate spacer 164 as an etching mask. The etching process may include a dry etching process and/or a wet etching process. In an example embodiment, two first recesses 180 may be formed adjacent to both sidewalls of the second gate structure 154, respectively.

Referring to FIG. 11, after removing the first mask 170, a second impurity region 190 may be formed on the substrate 100 to fill the first recess 180.

In an example embodiment, a first selective epitaxial growth (SEG) process may be performed using an upper portion of the substrate 100 exposed by the first recess 180 as a seed to form the second impurity region 190. When the first SEG process is performed, the first capping layer 160 may cover the first region I of the substrate 100, and thus no impurity region may be formed on the substrate 100 in the first region I. In an example embodiment, two second impurity regions 190 may be formed adjacent to both sidewalls of the second gate structure 154, respectively.

In an example embodiment, the first SEG process may be performed at a temperature of about 500 to about 900° C. under a pressure of about 0.1 torr to normal pressure by a chemical vapor deposition (CVD) process. The CVD process may be performed using a silicon source gas, e.g., dichlorosilane gas, a germanium source gas, e.g., germane gas, and p-type impurity source gas, e.g., diborane gas, and thus a single crystalline silicon-germanium layer doped with p-type impurities may be formed.

In an example embodiment, by controlling a flow rate of the germanium source gas, the single crystalline silicon-germanium layer may be formed to have a germanium concentration gradient. In an example embodiment, by gradually increasing the flow rate of the germanium source gas provided in the first SEG process as time goes by, a germanium concentration of the single crystalline silicon-germanium layer may be gradually increased. Thus, the single crystalline silicon-germanium layer may have a germanium concentration that becomes higher from a bottom portion to a top portion thereof, i.e., that may increase according to a distance from the substrate 100. In this case, the flow rate of the germanium source gas may be continuously increased or discontinuously increased in a shape of stairs, and thus the silicon-germanium layer may have a germanium concentration gradient that may vary continuously or discontinuously.

The second impurity regions 190 including the single crystalline silicon-germanium layer together with the second gate structure 154 may form a PMOS transistor, and thus the second impurity regions 190 may serve as second source/drain regions of the PMOS transistor.

Referring to FIG. 12, a Fermi level pinning layer 200 may be formed on the second impurity region 190.

The Fermi level pinning layer 200 may be formed to include a material that may pin a Fermi level of a metal layer or a metal silicide layer to a given energy level when it contacts the metal layer or the metal silicide layer. In an example embodiment, the Fermi level pinning layer 200 may be formed to include a material that may pin a Fermi level of a metal layer or a metal nitride layer contacting the Fermi level pinning layer 200 to a level near an edge of a valence band at an interface therebetween, e.g., to a level within about 0.1 eV range from the edge of the valence band.

In an example embodiment, the Fermi level pinning layer 200 may be formed to include a germanium layer. The germanium layer may pin a Fermi level of a subsequently formed second metal silicide layer 274 (refer to FIG. 17) contacting the germanium layer to a level higher than an edge of a valence band of the germanium layer at an interface therebetween by about 0.09 eV.

The germanium layer may be formed by a second SEG process, which may be performed under process conditions similar to those of the first SEG process. However, only the germanium source gas with no silicon source gas and no p-type impurity source gas may be used therein.

In an example embodiment, the first and second SEG processes may be performed in-situ. That is, after performing the first SEG process, under substantially the same conditions, providing the silicon source gas and the p-type impurity source gas may be stopped, and only the germanium source may be provided to perform the second SEG process.

In an example embodiment, by an ion implantation process, p-type impurities may be implanted into the germanium layer. The p-type impurities may include, e.g., gallium.

The Fermi level pinning layer 200 may be formed to have a thin thickness, e.g., several angstroms to about 10 nanometers.

Referring to FIG. 13, a second silicon layer 214 may be formed on the Fermi level pinning layer 200.

In an example embodiment, the second silicon layer 214 may be formed by a third SEG process. The third SEG process may be performed using the Fermi level pinning layer 200 and the underlying second impurity region 190 as a seed under process conditions similar to those of the first and second SEG processes. That is, the third SEG process may be performed using only the silicon source gas with no germanium source gas and no p-type impurity source gas.

In an example embodiment, the third SEG process may be formed in-situ with the first and second SEG processes.

As the Fermi level pinning layer 200 is formed to have a thin thickness, the third SEG process may be performed substantially using the second region 190 beneath the Fermi level pinning layer 200, e.g., the single crystalline silicon-germanium layer as a seed, so that a single crystalline second silicon layer 214 may be formed.

Referring to FIG. 14, a second capping layer 220 may be formed on the second gate structure 154, the second gate spacer 164, the second silicon layer 214, the isolation layer 110 and the first capping layer 160, a second mask 230 covering the second region II may be formed, and a portion of the second capping layer 220 in the first region I and the first capping layer 160 may be etched using the second mask 230 as an etching mask to expose a top surface of the substrate 100 in the first region I.

In an example embodiment, the etching process may be performed by an anisotropic etching process. Thus, a first gate spacer 162 may be formed on a sidewall of the first gate structure 152 in the first region I, and the second capping layer 220 may still remain on the substrate 100 in the second region II.

An exposed upper portion of the substrate 100 in the first region I may be removed to form a second recess 240. That is, an etching process using the second mask 230, the first gate structure 152 and the first gate spacer 162 as an etching mask may be performed to form the second recess 240. The etching process may include a dry etching process and/or a wet etching process. In an example embodiment, two second recesses 240 may be formed adjacent to both sidewalls of the first gate structure 152, respectively.

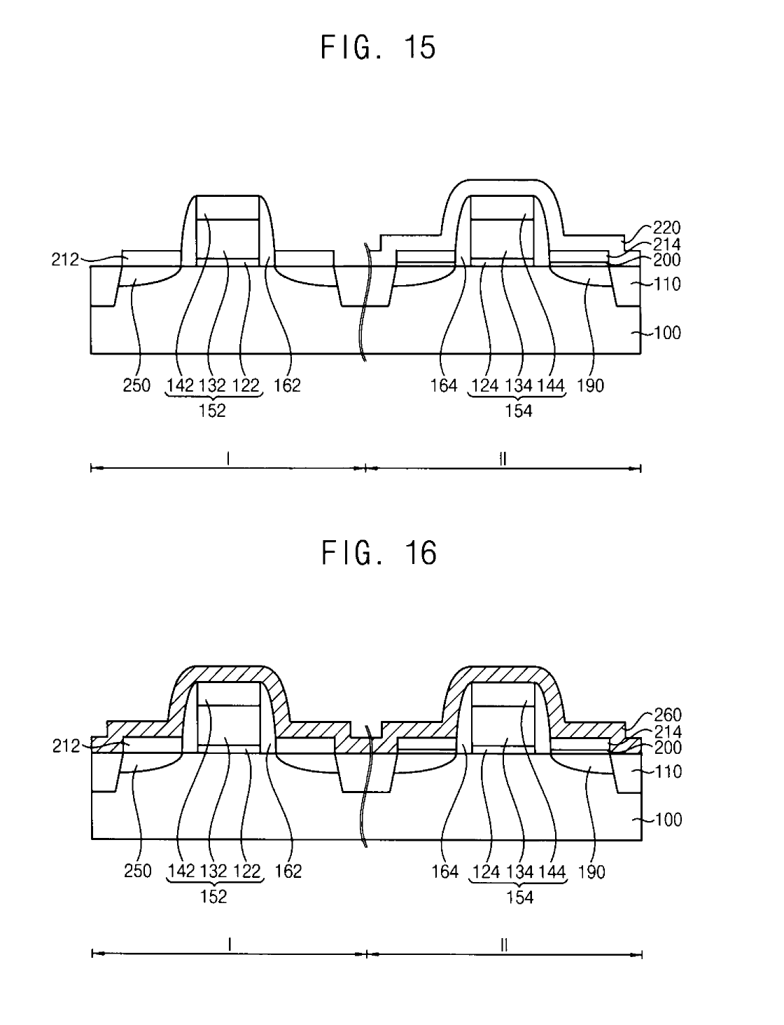

Referring to FIG. 15, after removing the second mask 230, a first impurity region 250 may be formed on the substrate 100 to fill the second recess 240.

In an example embodiment, a fourth SEG process may be performed using an upper portion exposed by the second recess 240 to form the first impurity region 250. When the fourth SEG process is performed, the second capping layer 220 may cover the second region II of the substrate 100, and thus no impurity region may be formed on the substrate 100 in the second region II. In an example embodiment, two first impurity regions 250 may be formed adjacent to both sidewalls of the first gate structure 152, respectively.

The fourth SEG process may be performed by a CVD process under process conditions similar to those of the first to third SEG processes. However, the CVD process may be performed using a silicon source gas, e.g., disilane gas, a carbon source gas, e.g., SiH₃CH₃ gas, and an n-type impurity source gas, e.g., phosphine gas, and thus a single crystalline silicon carbide layer doped with n-type impurities may be formed.

The first impurity regions 250 including the single crystalline silicon carbide layer together with the first gate structure 152 may form an NMOS transistor, and thus the first impurity regions 250 may serve as first source/drain regions of the NMOS transistor.

A first silicon layer 212 may be formed on the first impurity region 250.

In an example embodiment, the first silicon layer 212 may be formed by a fifth SEG process. The fifth SEG process may be performed using the first impurity region 250 as a seed under process conditions similar to those of the first to fourth SEG processes. That is, the fifth SEG process may be performed using only the silicon source gas with no germanium source gas and no impurity source gas.

In an example embodiment, the fifth SEG process may be performed in-situ with the fourth SEG process.

The fifth SEG process may be performed using the first impurity region 250, e.g., the single crystalline silicon carbide layer as a seed, and thus a single crystalline first silicon layer 212 may be formed.

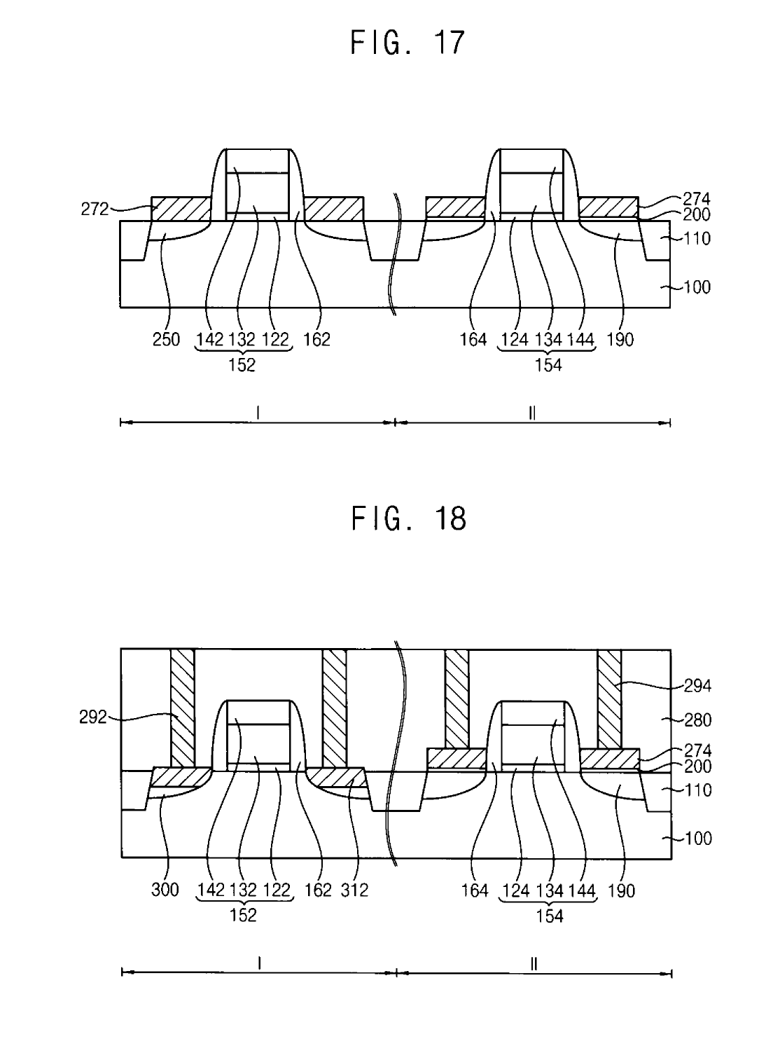

Referring to FIG. 16, after removing the second capping layer 220, a metal layer 260 may be formed on the substrate 100 having the first and second gate structures 152 and 154, the first and second gate spacers 162 and 164, the Fermi level pinning layer 200, the first and second silicon layers 212 and 214 and the isolation layer 110 thereon.

The metal layer 260 may be formed to include a metal having a relatively low work function, e.g., a rare earth metal.

Referring to FIG. 17, an annealing process may be performed on the substrate 100 so that the first and second silicon layers 212 and 214 and the metal layer 260 may be reacted with each other to form first and second metal silicide layers 272 and 274, respectively.

In the annealing process, at least a portion of the first and second silicon layers 212 and 214 may be reacted with the metal layer 260. When the whole portion of the first and second silicon layers 212 and 214 are reacted with the metal layer 260, the first and second metal silicide layers 272 and 274 may be formed on the first impurity region 250 and the Fermi level pinning layer 200, respectively. When only a portion of the first and second silicon layers 212 and 214 are reacted with the metal layer 260, a portion of the first and second silicon layers 212 and 214 may remain beneath the first and second metal silicide layers 272 and 274, respectively.

A portion of the metal layer 260 that has not been reacted with the first and second silicon layers 212 and 214 in the annealing process may be removed.

Referring to FIG. 1 again, an insulating interlayer 280 may be formed on the substrate 100 having the first and second gate structures 152 and 154, the first and second gate spacers 162 and 164, the first and second impurity regions 250 and 190, the Fermi level pinning layer 200, the first and second metal silicide layers 272 and 274, and the isolation layer 110, and first and second contact plugs 292 and 294 may be formed through the insulating interlayer 280 to contact the first and second metal silicide layers 272 and 274, respectively.

The insulating interlayer 280 may be formed to include, e.g., silicon oxide.

The first and second contact plugs 292 and 294 may be formed by partially removing the insulating interlayer 280 to form first and second contact holes (not shown) exposing the first and second metal silicide layers 272 and 274, respectively, forming a conductive layer on the first and second metal silicide layers 272 and 274 and the insulating interlayer 280 to sufficiently fill the first and second contact holes, and planarizing an upper portion of the conductive layer until a top surface of the insulating interlayer 280 may be exposed.

The conductive layer may be formed to include, e.g., a metal, a metal nitride, a metal silicide, etc.

FIG. 18 is a cross-sectional view illustrating a semiconductor device in accordance with an example embodiment. This semiconductor device may be substantially the same as or similar to that of FIG. 1, except for the impurity region and the metal silicide layer. Thus, like reference numerals refer to like elements, and detailed descriptions thereon are omitted herein.

Referring to FIG. 18, the semiconductor device may include a first gate structure 152, a third impurity region 300, a third metal silicide layer 312 and a first contact plug 292 on a substrate 100 in a first region I, and a second gate structure 154, a second impurity region 190, a Fermi level pinning layer 200, a second metal silicide layer 274 and a second contact plug 294 on the substrate 100 in a second region II. The semiconductor device may further include first and second gate spacers 162 and 164 on sidewalls of the first and second gate structures 152 and 154, respectively.

The third impurity region 300 may be formed at an upper portion of the substrate 100 adjacent to the first gate structure 152, and thus may include silicon when the substrate 100 is a silicon substrate. In an example embodiment, two third impurity regions 300 may be formed at upper portions of the substrate 100 adjacent to sidewalls of the first gate structure 152. For example, the third impurity region 300 may include n-type impurities, e.g., phosphorus, arsenic, etc.

The third metal silicide layer 312 may include a metal substantially the same as that of the second metal silicide layer 274. That is, the third metal silicide layer 312 may include a metal having a relatively low work function, e.g., a rare earth metal.

The third metal silicide layer 312 may be formed in the third impurity region 300, or a portion of the third metal silicide layer 312 may be formed at an outside of the third impurity region 300. The third metal silicide layer 312 may have a top surface substantially coplanar with or higher than a top surface of the substrate 100 and lower than a top surface of the second metal silicide layer 274. Additionally, the third metal layer 312 may further include n-type impurities doped in the third impurity region 300.

The semiconductor device may also have and a relatively low second contact resistance between the second impurity region 190 and the second contact plug 294 and a relatively low third contact resistance between the third impurity region 300 and the first contact plug 292, through the first and second metal silicide layers 272 and 274 and the Fermi level pinning layer 200, like the semiconductor device of FIG. 1.

FIGS. 19 to 21 are cross-sectional views illustrating stages of a method of manufacturing a semiconductor device in accordance with another example embodiment. This method may be used in manufacturing the semiconductor device of FIG. 18, however, may not be limited thereto. Additionally, this method may include processes substantially the same as or similar to those illustrated with reference to FIGS. 8 to 17. Thus, like reference numerals refer to like elements, and detailed descriptions thereon are omitted herein.

First, processes substantially the same as or similar to those illustrated with reference to FIGS. 8 to 13 may be performed.

Referring to FIG. 19, after forming a second mask 230 covering the second region II, the first capping layer 160 may be etched using the second mask 230 as an etching mask to expose a top surface of the substrate 100 in the first region I.

In another example embodiment, the etching process may be performed by a dry etching process, and thus a first gate spacer 162 may be formed on a sidewall of the first gate structure 152 in the first region I.

N-type impurities may be implanted into an exposed upper portion of the substrate 100 in the first region I using the second mask 230, the first gate structure 152 and the first gate spacer 162 as an ion implantation mask to form a third impurity region 300. In another example embodiment, two third impurity regions 300 may be formed at upper portions of the substrate 100 adjacent to sidewalls of the first gate structure 152.

The third impurity regions 300 including the n-type impurities together with the first gate structure 152 may form an NMOS transistor, and thus the third impurity regions 300 may serve as third source/drain regions of the NMOS transistor.

The second mask 230 may be removed.

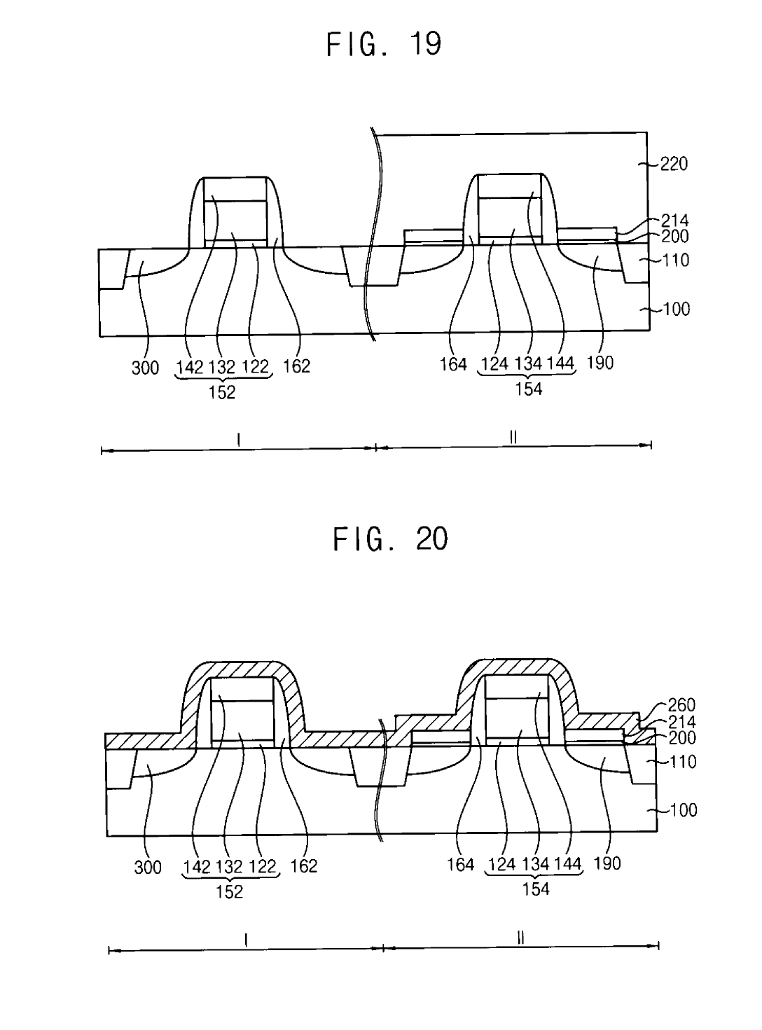

Referring to FIG. 20, a process substantially the same as or similar to that illustrated with reference to FIG. 16 may be performed.

That is, a metal layer 260 may be formed on the substrate 100 having the first and second gate structures 152 and 154, the first and second gate spacers 162 and 164, the Fermi level pinning layer 200, the second silicon layer 214, the third impurity region 300, and the isolation layer 110 thereon.

The metal layer 260 may be formed to include a metal having a relatively low work function, e.g., a rare earth metal.

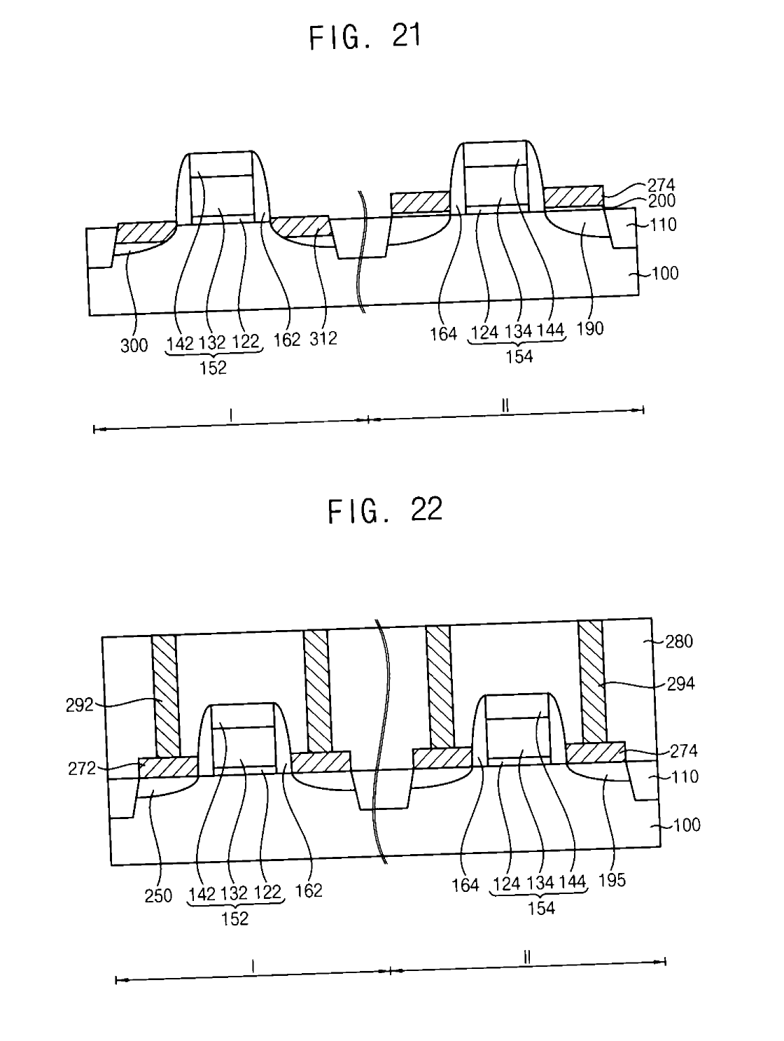

Referring to FIG. 21, a process substantially the same as or similar to that illustrated with reference to FIG. 17 may be performed.

That is, an annealing process may be performed on the substrate 100 so that the second silicon layer 214 and the third impurity region 300 and the metal layer 260 may be reacted with each other to form second and third metal silicide layers 274 and 312, respectively. A portion of the metal layer 260 that has not been reacted with the second silicon layer 214 and the third impurity region 300 in the annealing process may be removed. The third metal silicide layer 312 may be formed in the third impurity region 300, or a portion of the third metal silicide layer 312 may be formed at an outside of the third impurity region 300. Additionally, the third metal silicide layer 312 may further include n-type impurities doped in the third impurity region 300.

Referring to FIG. 18 again, a process substantially the same as or similar to that illustrated with reference to FIG. 1 may be performed.

That is, an insulating interlayer 280 may be formed on the substrate 100 having the first and second gate structures 152 and 154, the first and second gate spacers 162 and 164, the second and third impurity regions 190 and 300, the Fermi level pinning layer 200, the second and third metal silicide layers 274 and 312, and the isolation layer 110, and first and second contact plugs 292 and 294 may be formed through the insulating interlayer 280 to contact the third and second metal silicide layers 312 and 274, respectively.

The insulating interlayer 280 may be formed to include, e.g., silicon oxide.

The first and second contact plugs 292 and 294 may be formed by partially removing the insulating interlayer 280 to form first and second contact holes (not shown) exposing the first and second metal silicide layers 272 and 274, respectively, forming a conductive layer on the first and second metal silicide layers 272 and 274 and the insulating interlayer 280 to sufficiently fill the first and second contact holes, and planarizing an upper portion of the conductive layer until a top surface of the insulating interlayer 280 may be exposed.

The conductive layer may be formed to include, e.g., a metal, a metal nitride, a metal silicide, etc.

FIG. 22 is a cross-sectional view illustrating a semiconductor device in accordance with another example embodiment. This semiconductor device may be substantially the same as or similar to that of FIG. 1, except for the Fermi level pinning layer and the impurity region. Thus, like reference numerals refer to like elements, and detailed descriptions thereon are omitted herein.

Referring to FIG. 22, the semiconductor device may include a first gate structure 152, a first impurity region 250, a first metal silicide layer 272 and a first contact plug 292 on a substrate 100 in a first region I, and a second gate structure 154, a fourth impurity region 195, a second metal silicide layer 274 and a second contact plug 294 on the substrate 100 in a second region II. The semiconductor device may further include first and second gate spacers 162 and 164 on sidewalls of the first and second gate structures 152 and 154, respectively.

The fourth impurity region 195 may be substantially the same as the second impurity region 190 of FIG. 1, except for the germanium concentration.

That is, the fourth impurity region 195 may include a single crystalline silicon-germanium layer doped with p-type impurities, and the single crystalline silicon-germanium layer may have a germanium concentration gradient that becomes higher from a bottom portion to a top portion thereof. The germanium concentration may increase from the bottom portion to the top portion thereof continuously or discontinuously, e.g., in a shape of stairs.

At least a top portion of the fourth impurity region 195 may have a germanium concentration higher than that of the second impurity region 190. That is, the fourth impurity region 195 may include a silicon-germanium layer of which a top portion has a germanium concentration equal to or more than about 60%. In an example embodiment, the top portion of the silicon-germanium layer may have a germanium concentration of about 100%. In this case, the top portion of the silicon-germanium layer may be a germanium layer substantially free of silicon, and may serve as the Fermi level pinning layer 200 of FIG. 1. That is, the fourth impurity region 195 may serve as both of the second impurity region 195 and the Fermi level pinning layer 200 of the semiconductor device of FIG. 1.

This semiconductor device may be manufactured by processes substantially the same as or similar to those illustrated with reference to FIGS. 8 to 17. That is, the second SEG process for forming the Fermi level pinning layer 200 may be skipped, and the other processes may be performed to manufacture the semiconductor device.

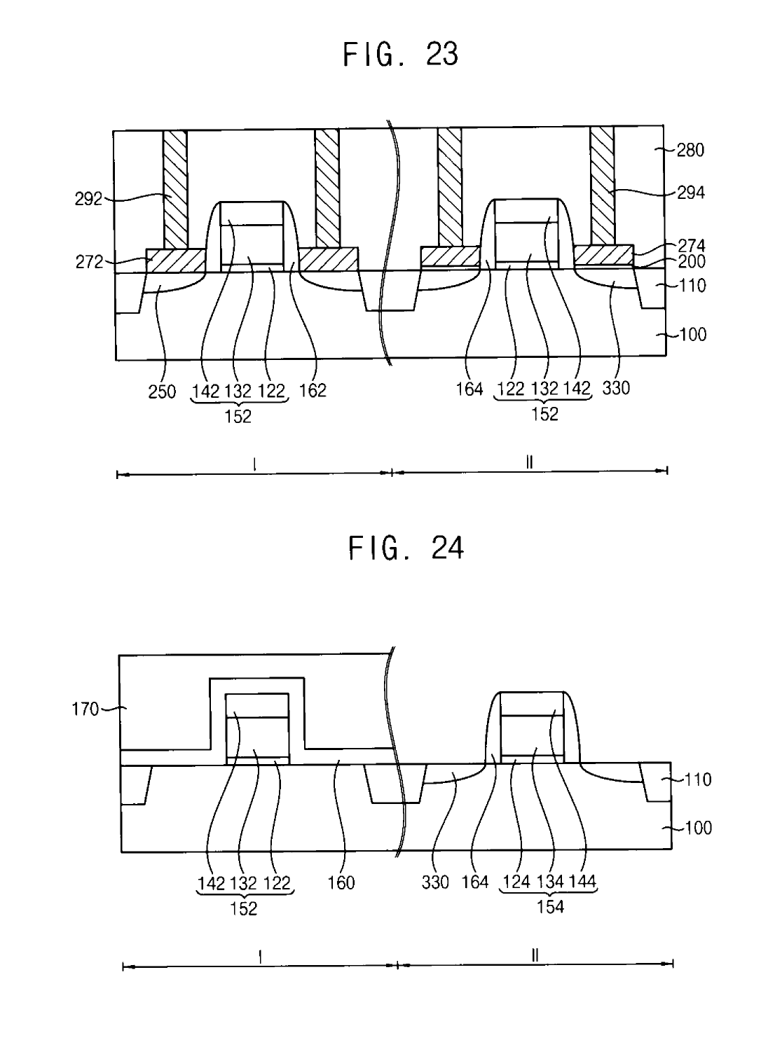

FIG. 23 is a cross-sectional view illustrating a semiconductor device in accordance with another example embodiment. This semiconductor device may be substantially the same as or similar to that of FIG. 1, except for the impurity region. Thus, like reference numerals refer to like elements, and detailed descriptions thereon are omitted herein.

Referring to FIG. 23, the semiconductor device may include a first gate structure 152, a first impurity region 250, a first metal silicide layer 272 and a first contact plug 292 on a substrate 100 in a first region I, and a second gate structure 154, a fifth impurity region 330, a Fermi level pinning layer 200, a second metal silicide layer 274 and a second contact plug 294 on the substrate 100 in a second region II. The semiconductor device may further include first and second gate spacers 162 and 164 on sidewalls of the first and second gate structures 152 and 154, respectively.

The fifth impurity region 330 may be formed at an upper portion of the substrate 100 adjacent to the second gate structure 154. Thus, the fifth impurity region 300 may include silicon when the substrate 100 is a silicon substrate. The fifth impurity region 330 may include p-type impurities, e.g., boron, gallium, etc. In another example embodiment, two fifth impurity regions 330 may be formed at upper portions of the substrate 100 adjacent to sidewalls of the second gate structure 154.

The fifth impurity regions 330 together with the second gate structure 154 may form a PMOS transistor, and the fifth impurity regions 330 may serve as source/drain regions of the PMOS transistor.

The semiconductor device may include a germanium layer serving as the Fermi level pinning layer 200 on the fifth impurity region 330 doped with p-type impurities like the semiconductor device of FIG. 1, and thus may have and a relatively low contact resistance between the fifth impurity region 330 and the second contact plug 294.

FIGS. 24 to 27 are cross-sectional views illustrating stages of a method of manufacturing a semiconductor device in accordance with another example embodiment. This method may be used in manufacturing the semiconductor device of FIG. 23, however, may not be limited thereto. Additionally, this method may include processes substantially the same as or similar to those illustrated with reference to FIGS. 8 to 17, and thus like reference numerals refer to like elements, and detailed descriptions thereon are omitted herein.

First, processes substantially the same as or similar to those illustrated with reference to FIGS. 8 to 9 may be performed.

Referring to FIG. 24, a first mask 170 covering the first region I may be formed on the first capping layer 160, and a portion of the first capping layer 160 in the second region II may be etched using the first mask 170 as an etching mask to expose a top surface of the substrate 100.

In another example embodiment, the etching process may be performed by an anisotropic etching process. Thus, the first capping layer 160 may remain only on a sidewall of the second gate structure 154 in the second region II, and hereinafter, may be referred to as a second gate spacer 164. In the first region I, the first capping layer 160 may still remain on the substrate 100.

P-type impurities may be implanted into an upper portion of the substrate 100 in the second region II by an ion implantation process to form a fifth impurity region 330.

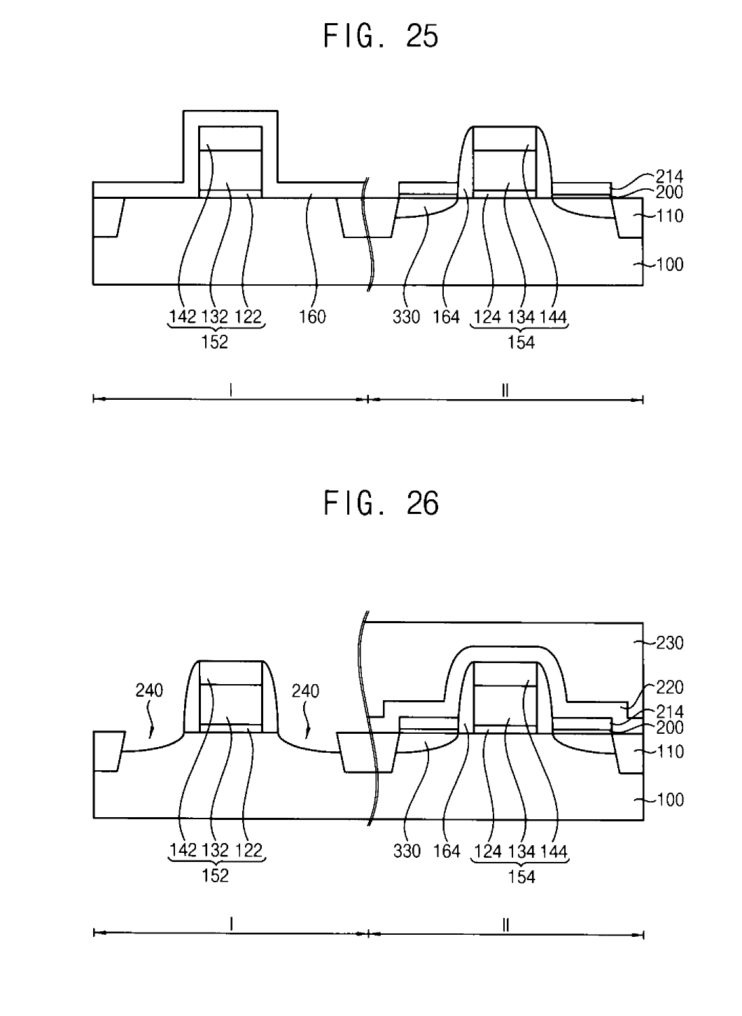

Referring to FIG. 25, processes substantially the same as or similar to those illustrated with reference to FIGS. 11 to 13 may be performed.

That is, after removing the first mask 170, a Fermi level pinning layer 200 and a second silicon layer 214 may be sequentially formed on the fifth impurity region 330.

Referring to FIG. 26, a process substantially the same as or similar to that illustrated with reference to FIG. 14 may be performed.

That is, a second capping layer 220 may be formed on the second gate structure 154, the second gate spacer 164, the second silicon layer 214, the isolation layer 110 and the first capping layer 160, a second mask 230 covering the second region II may be formed, and a portion of the second capping layer 220 in the first region I and the first capping layer 160 may be etched using the second mask 230 as an etching mask to expose a top surface of the substrate 100 in the first region I. An exposed upper portion of the substrate 100 in the first region I may be removed to form a second recess 240.

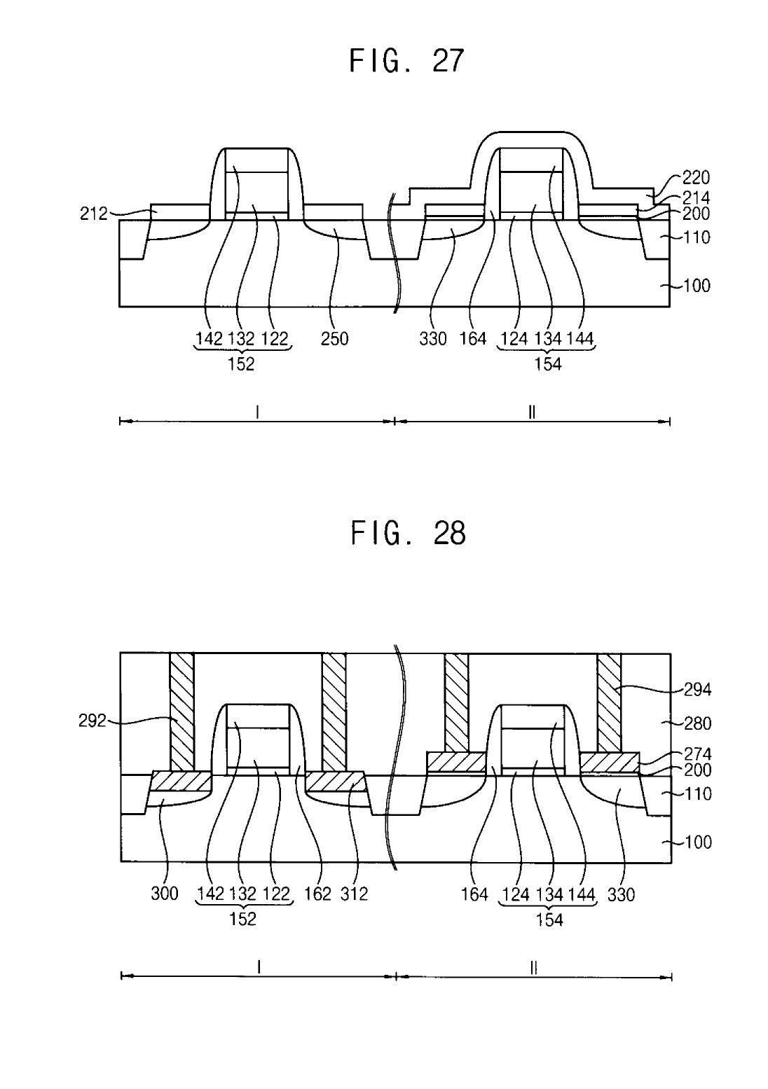

Referring to FIG. 27, a process substantially the same as or similar to that illustrated with reference to FIG. 15 may be performed.

That is, after removing the second mask 230, a first impurity region 250 may be formed on the substrate 100 by a SEG process to fill the second recess 240. A first silicon layer 212 may be formed on the first impurity region 250.

Referring to FIG. 23 again, processes substantially the same as or similar to those illustrated with reference to FIGS. 16 to 17 and FIG. 1 may be performed.

That is, after removing the second capping layer 220, a metal layer 260 may be formed on the substrate 100 having the first and second gate structures 152 and 154, the first and second gate spacers 162 and 164, the Fermi level pinning layer 200, the first and second silicon layers 212 and 214 and the isolation layer 110 thereon. An annealing process may be performed on the substrate 100 so that the first and second silicon layers 212 and 214 and the metal layer 260 may be reacted with each other to form first and second metal silicide layers 272 and 274, respectively. An insulating interlayer 280 may be formed on the substrate 100 having the first and second gate structures 152 and 154, the first and second gate spacers 162 and 164, the first and fifth impurity regions 250 and 330, the Fermi level pinning layer 200, the first and second metal silicide layers 272 and 274, and the isolation layer 110, and first and second contact plugs 292 and 294 may be formed through the insulating interlayer 280 to contact the first and second metal silicide layers 272 and 274, respectively.

FIG. 28 is a cross-sectional view illustrating a semiconductor device in accordance with another example embodiment. This semiconductor device may be substantially the same as or similar to that of FIG. 1, except for the impurity region and the metal silicide layer. Thus, like reference numerals refer to like elements, and detailed descriptions thereon are omitted herein.

Referring to FIG. 28, the semiconductor device may include a first gate structure 152, a third impurity region 300, a third metal silicide layer 312 and a first contact plug 292 on a substrate 100 in a first region I, and a second gate structure 154, a fifth impurity region 330, a Fermi level pinning layer 200, a second metal silicide layer 274 and a second contact plug 294 on the substrate 100 in a second region II. The semiconductor device may further include first and second gate spacers 162 and 164 on sidewalls of the first and second gate structures 152 and 154, respectively.

The third impurity region 300 and the third metal silicide layer 312 may be substantially the same as those of the semiconductor device illustrated with reference to FIG. 18, respectively, and the fifth impurity region 330 may be substantially the same as that of the semiconductor device illustrated with reference to FIG. 23.

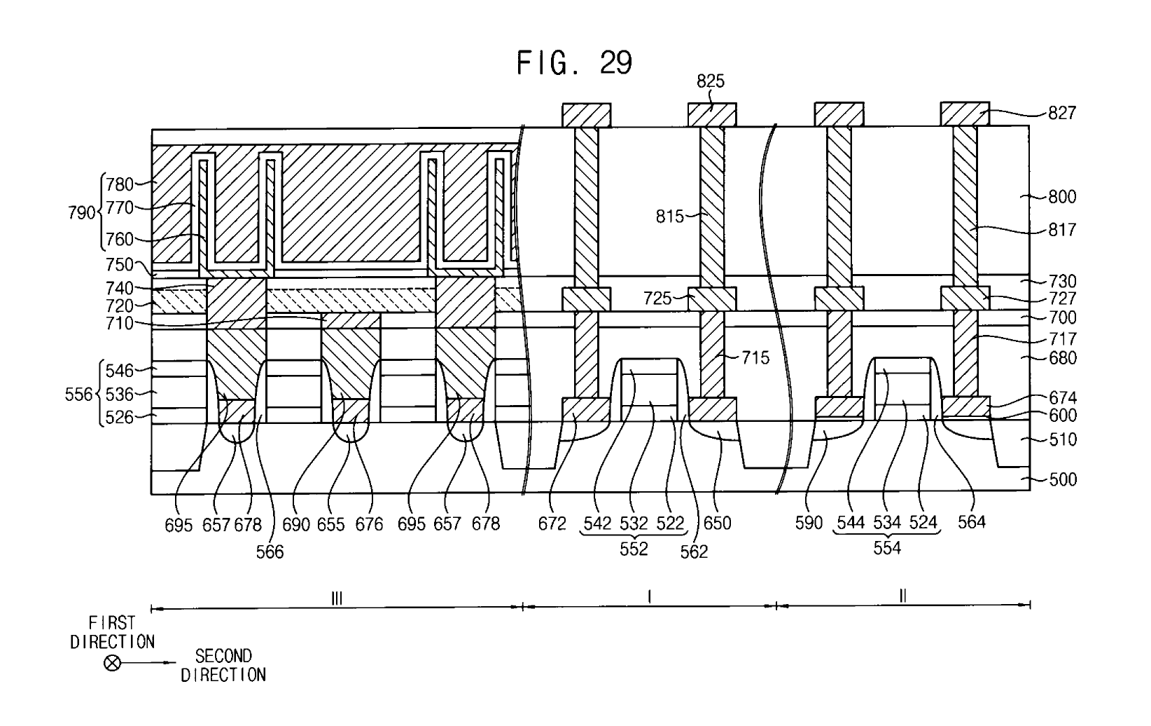

FIG. 29 is a semiconductor device in accordance with another example embodiment. This semiconductor device may include structures substantially the same as or similar to those of the semiconductor device illustrated with reference to FIG. 1, and thus detailed descriptions thereon are omitted herein. That is, the semiconductor device may be a dynamic random access memory (DRAM) device to which the present inventive concepts are applied. First and second regions I and II serving as a peripheral region or a logic region of the DRAM device may correspond to the first and second regions I and II of FIG. 1, and a third region III may serve as a cell region of the DRAM device.

Referring to FIG. 29, the semiconductor device may include a first gate structure 552, a first impurity region 650, a first metal silicide layer 672 and a first contact plug 715 on the first region I of a substrate 500, a second gate structure 554, a second impurity region 590, a Fermi level pinning layer 600, a second metal silicide layer 674 and a second contact plug 717 on the second region II of the substrate 500, and a third gate structure 556, third and fourth impurity regions 655 and 657, third and fourth metal silicide layers 676 and 678, and third and fourth contact plugs 690 and 695 on the third region II of the substrate 500. The semiconductor device may further include first to third gate spacers 562, 564 and 566 on sidewalls of the first to third gate structures 552, 554 and 556, respectively, first and third wirings 725 and 825 and a seventh contact plug 815 on the first region I of the substrate 500, second and fourth wirings 727 and 827 and an eighth contact plug 817 on the third region III of the substrate 500, and fifth and sixth contact plugs 710 and 740, a bit line 720 and a capacitor 790 on the third region III of the substrate 500.

The substrate 500 may be a semiconductor substrate, e.g., a silicon substrate, or an SOI substrate. The substrate 500 may include the first, second and third regions I, II and III. The third region III may serve as a cell region in which memory cells are formed, and the first and second regions I and II may serve as a peripheral region or a logic region in which peripheral circuits are formed. Particularly, the first region I may be an NMOS region in which NMOS transistors are formed, the second region II may be a PMOS region in which PMOS transistors are formed, and the third region III may be an NMOS region in which NMOS transistors are formed. The substrate 500 may further include a well (not shown) doped with p-type or n-type impurities.

An isolation layer 510 may be formed on the substrate 500 to define an active region and a field region in the substrate 500.

The first gate structure 552 may include a first gate insulation layer pattern 522, a first gate electrode 532 and a first gate mask 542 sequentially stacked on the substrate 500. The second gate structure 554 may include a second gate insulation layer pattern 524, a second gate electrode 534 and a second gate mask 544 sequentially stacked on the substrate 500. The third gate structure 556 may include a third gate insulation layer pattern 526, a third gate electrode 536 and a third gate mask 546 sequentially stacked on the substrate 500.

In another example embodiment, the first to third gate insulation layer patterns 522, 524 and 526 may include substantially the same material, e.g., silicon oxide, a metal oxide, etc., the first to third gate electrodes 532, 534 and 536 may include substantially the same material, e.g., doped polysilicon, a metal, a metal nitride, a metal silicide, etc., and the first to third gate masks 542, 544 and 546 may include substantially the same material, e.g., silicon nitride.

In another example embodiment, the first gate structure 552 may extend in a first direction substantially parallel to a top surface of the substrate 500, and a plurality of first gate structures 552 may be formed in a second direction substantially parallel to the top surface of the substrate 500 and substantially perpendicular to the first direction. Each of the second and third gate structures 554 and 556 may extend in the first direction, and a plurality of second gate structures 554 and a plurality of third gate structures 556 may be formed in the second direction likewise.

The first to third gate spacers 562, 564 and 566 may include, e.g., silicon nitride and/or silicon oxide.

The first impurity region 650 may be formed on a portion of the substrate 500 adjacent to the first gate structure 552, the second impurity region 590 may be formed on a portion of the substrate 500 adjacent to the second gate structure 554, and the third and fourth impurity regions 655 and 657 may be formed on portions of the substrate 500 adjacent to the third gate structure 556. In another example embodiment, two first impurity regions 650 may be formed on portions of the substrate 500 adjacent to the sidewalls of the first gate structure 552, two second impurity regions 590 may be formed on portions of the substrate 500 adjacent to the sidewalls of the second gate structure 554. For example, the first, third and fourth impurity regions 650, 655 and 657 may include a single crystalline silicon carbide layer doped with n-type impurities, phosphorus, arsenic, etc. For example, the second impurity region 590 may include a single crystalline silicon-germanium layer doped with p-type impurities, e.g., boron, gallium, etc. The silicon-germanium layer may have a germanium concentration gradient that becomes higher from a bottom portion to a top portion thereof, and the germanium concentration may increase from the bottom portion to the top portion thereof continuously or discontinuously, e.g., in a shape of stairs.

The first gate structure 552 together with the first impurity regions 650 may form a first NMOS transistor, the second gate structure 554 together with the second impurity regions 590 may form a PMOS transistor, and the third gate structure 556 together with the third and fourth impurity regions 655 and 657 may form a second NMOS transistor.

The Fermi level pinning layer 600 may be formed on the second impurity region 590. In an example embodiment, the Fermi level pinning layer 600 may include a germanium layer. In an example embodiment, the germanium layer may be doped with p-type impurities, e.g., gallium.

The first to fourth metal silicide layers 672, 674, 676 and 678 may be formed on the first impurity region 650, the Fermi level pinning layer 600, the third impurity region 655 and the fourth impurity region 657, respectively. In another example embodiment, the first to fourth metal silicide layers 672, 674, 676 and 678 may include a rare earth metal.

The first to third gate structures 552, 554 and 556, the first to third gate spacers 562, 564 and 566, the first to fourth impurity regions 650, 590, 655 and 657, the Fermi level pinning layer 600, and the first to fourth metal silicide layers 672, 674, 676 and 678 may be covered by a first insulating interlayer 680, and the third and fourth contact plugs 690 and 695 may be formed through the first insulating interlayer 680 to contact top surfaces of the third and fourth metal silicide layers 676 and 678, respectively. The first insulating interlayer 680 may include an insulating material, e.g., silicon oxide, and the third and fourth contact plugs 690 and 695 may include, e.g., a metal, a metal nitride, a metal silicide, etc.

A second insulating interlayer 700 may be formed on the first insulating interlayer 680 and the third and fourth contact plugs 690 and 695, and the fifth contact plug 710 may be formed through the second insulating interlayer 700 to contact the third metal silicide layer 676. The first and second contact plugs 715 and 717 may be formed through the first and second insulating interlayers 680 and 700 to contact the first and second metal silicide layers 672 and 674, respectively. The second insulating interlayer 700 may include an insulating material, e.g., silicon oxide, and the first, second and fifth contact plugs 715, 717 and 710 may include, e.g., a metal, a metal nitride, a metal silicide, etc.

The bit line 720 and the first and second wirings 725 and 727 may be formed on the second insulating interlayer 700, and may be covered by a third insulating interlayer 730.

For example, the bit line 720 and the first and second wirings 725 and 727 may include a metal, a metal nitride, a metal silicide, etc., and the third insulating interlayer 730 may include silicon oxide. In another example embodiment, the bit line 720 may extend in the second direction.

The capacitor 790 may be electrically connected to the sixth contact plug 740. The capacitor 790 may include a lower electrode 760, a dielectric layer 770 and an upper electrode 780 sequentially stacked. The lower electrode 760 may contact the sixth contact plug 740. In another example embodiment, the lower electrode 760 may have a hollow cylindrical shape. Alternatively, the lower electrode 760 may have a pillar shape. The dielectric layer 770 may be formed on the lower electrode 760 and an etch stop layer 750 on the third insulating interlayer 730, and the upper electrode 780 may be formed on the dielectric layer 770.

For example, the lower and upper electrodes 760 and 780 may include, e.g., doped polysilicon, a metal, a metal nitride and/or a metal silicide, the dielectric layer 770 may include silicon oxide, silicon nitride, a metal oxide, etc., and the etch stop layer 750 may include, e.g., silicon nitride.

A fourth insulating interlayer 800 covering the capacitor 790 may be formed on the third insulating interlayer 730. The fourth insulating interlayer 800 may include, e.g., silicon oxide.

The seventh and eighth contact plugs 815 and 817 may be formed through the third and fourth insulating interlayers 730 and 800 to contact the first and second wirings 725 and 727, respectively. The third and fourth wirings 825 and 827 may be formed on the fourth insulating interlayer 800 to contact the seventh and eighth contact plugs 815 and 817, respectively. The seventh and eighth contact plugs 815 and 817 and the third and fourth wirings 825 and 827 may include, e.g., a metal, a metal nitride, a metal silicide, etc.

The contact plugs 715, 717, 690, 695, 710, 740, 815 and 817 and the wirings 725, 727, 825 and 827 may have various other layouts that are not the same as that of FIG. 29.

The semiconductor device may include the Fermi level pinning layer 600 between the second impurity region 590 and the second metal silicide layer 674, and thus may have a relatively low contact resistance between the second impurity region 590 and the second contact plug 717 even though the second metal silicide layer 674 includes a metal having a relatively low work function because of the Fermi level pinning.

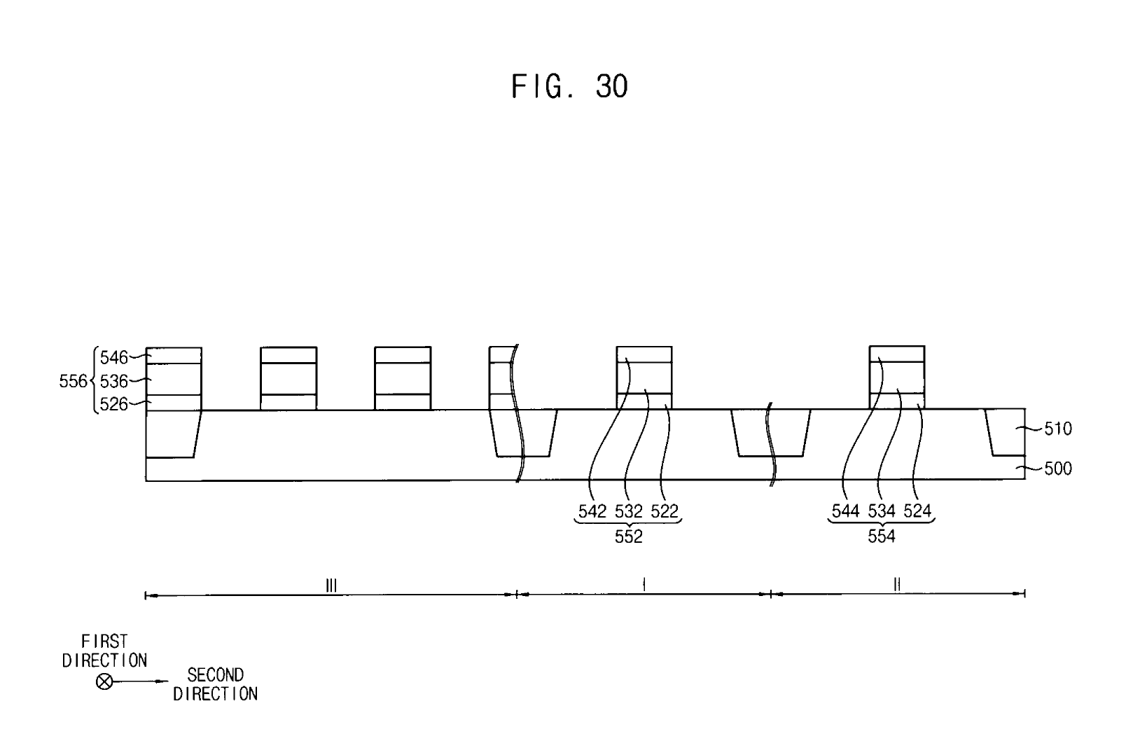

FIGS. 30 to 38 are cross-sectional views illustrating stages of a method of manufacturing a semiconductor device in accordance with another example embodiment. This method may be used in manufacturing the semiconductor device of FIG. 29, however, may not be limited thereto. Additionally, this method may include processes substantially the same as or similar to those illustrated with reference to FIGS. 8 to 17, and thus, detailed descriptions thereon are omitted herein.

Referring to FIG. 30, a process substantially the same as or similar to that illustrated with reference to FIG. 8 may be performed.

That is, first, second and third gate structures 552, 554 and 556 may be formed on first, second and third regions I, III and III, respectively, of a substrate 500 having an isolation layer 510 thereon.

The first, second and third gate structures 552, 554 and 556 may be formed by sequentially forming a gate insulation layer, a gate electrode layer and a gate mask layer on the substrate 500, and patterning the gate mask layer, the gate electrode layer and the gate insulation layer through a photolithography process. Thus, the first gate structure 552 may be formed to include a first gate insulation layer pattern 522, a first gate electrode 532 and a first gate mask 542 sequentially stacked on the substrate 500 in the first region I, the second gate structure 554 may be formed to include a second gate insulation layer pattern 524, a second gate electrode 534 and a second gate mask 544 sequentially stacked on the substrate 500 in the second region II, and the third gate structure 556 may be formed to include a third gate insulation layer pattern 526, a third gate electrode 536 and a third gate mask 546 sequentially stacked on the substrate 500 in the third region III.

In another example embodiment, the first gate structure 552 may be formed to extend in a first direction substantially parallel to a top surface of the substrate 500, and a plurality of first gate structures 552 may be formed in a second direction substantially parallel to the top surface of the substrate 500 and substantially perpendicular to the first direction. Each of the second and third gate structure 554 and 556 may be formed to extend in the first direction, and a plurality of second gate structures 554 and a plurality of third gate structures 556 may be formed in the second direction likewise.

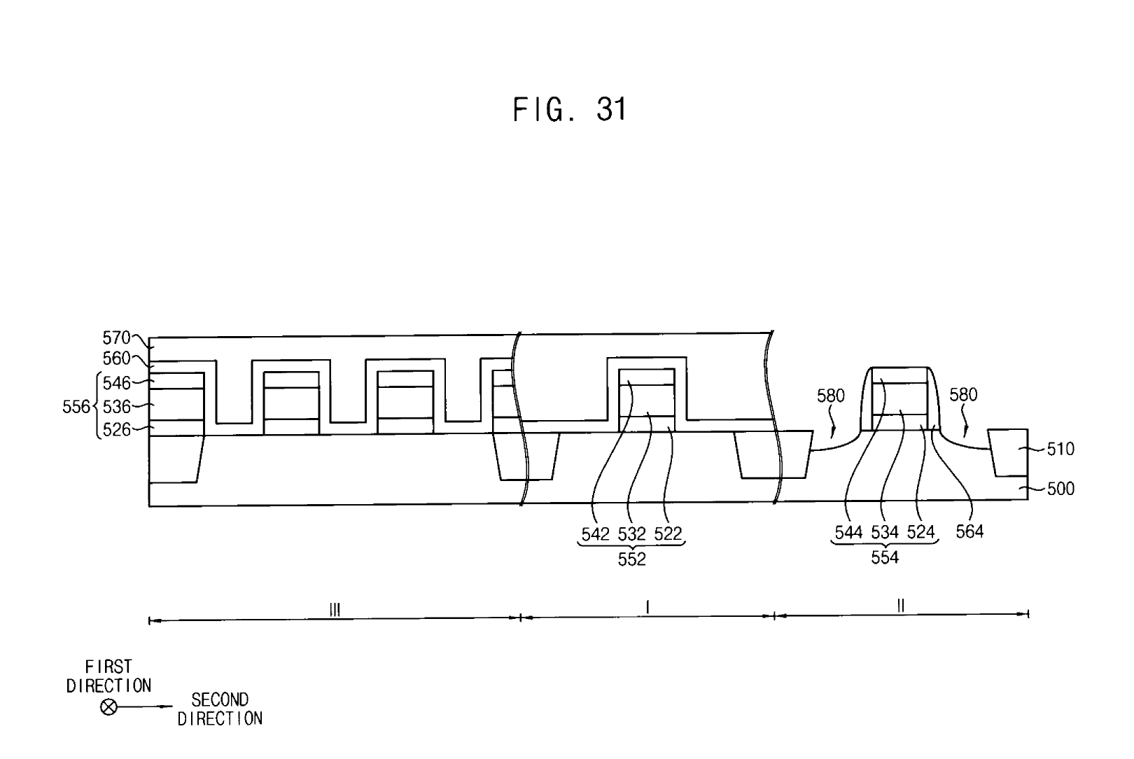

Referring to FIG. 31, processes substantially the same as or similar to those illustrated with reference to FIGS. 9 to 10 may be performed.

That is, a first capping layer 560 may be formed on the substrate 500 to cover the first to third gate structures 552, 554 and 556, a first mask 570 covering the first and third regions I and III may be formed on the first capping layer 560, and a portion of the first capping layer 560 in the second region II may be etched using the first mask 570 as an etching mask to expose a top surface of the substrate 500 in the second region II. In the second region II, the first capping layer 560 may remain only on a sidewall of the second gate structure 554, which may be referred to as a second gate spacer 564, and in the first and third regions I and III, the first capping layer 560 may still remain on the substrate 500.

An exposed upper portion of the substrate 500 in the second region II may be removed to form a first recess 580.

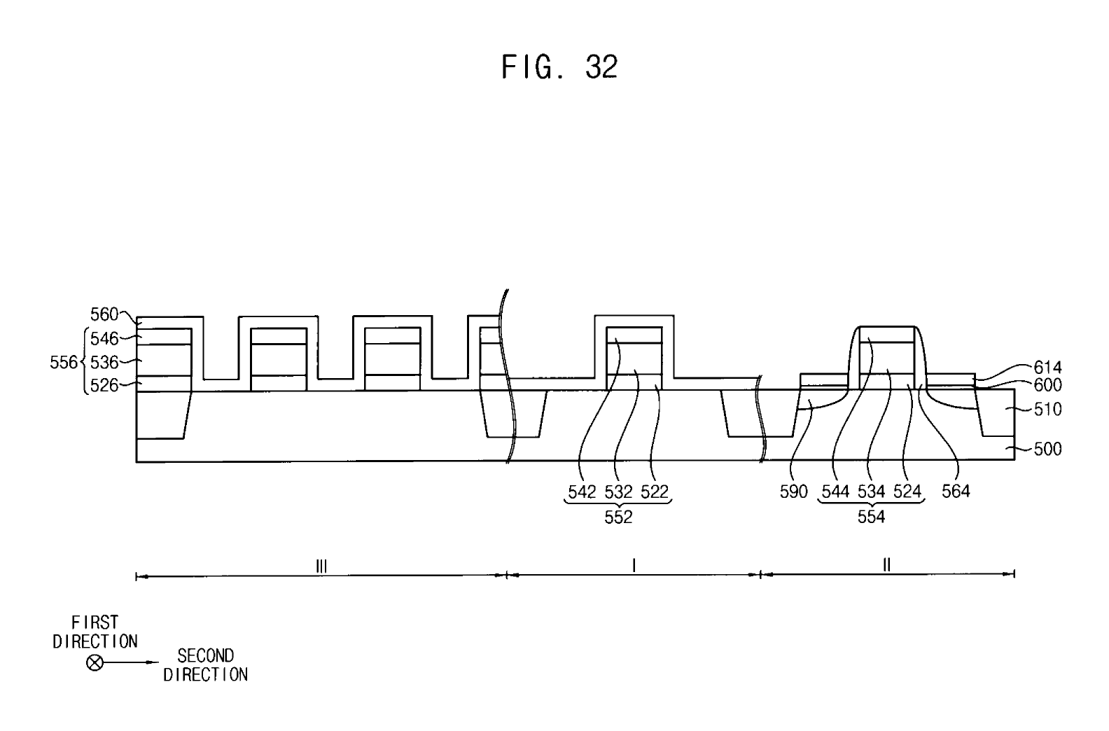

Referring to FIG. 32, processes substantially the same as or similar to those illustrated with reference to FIGS. 11 to 13 may be performed.

That is, after removing the first mask 570, a second impurity region 590 may be formed on the substrate 500 by a first SEG process to fill the first recess 580, and a Fermi level pinning layer 600 and a second silicon layer 614 may be sequentially formed on the second impurity region 590 by second and third SEG processes, respectively.

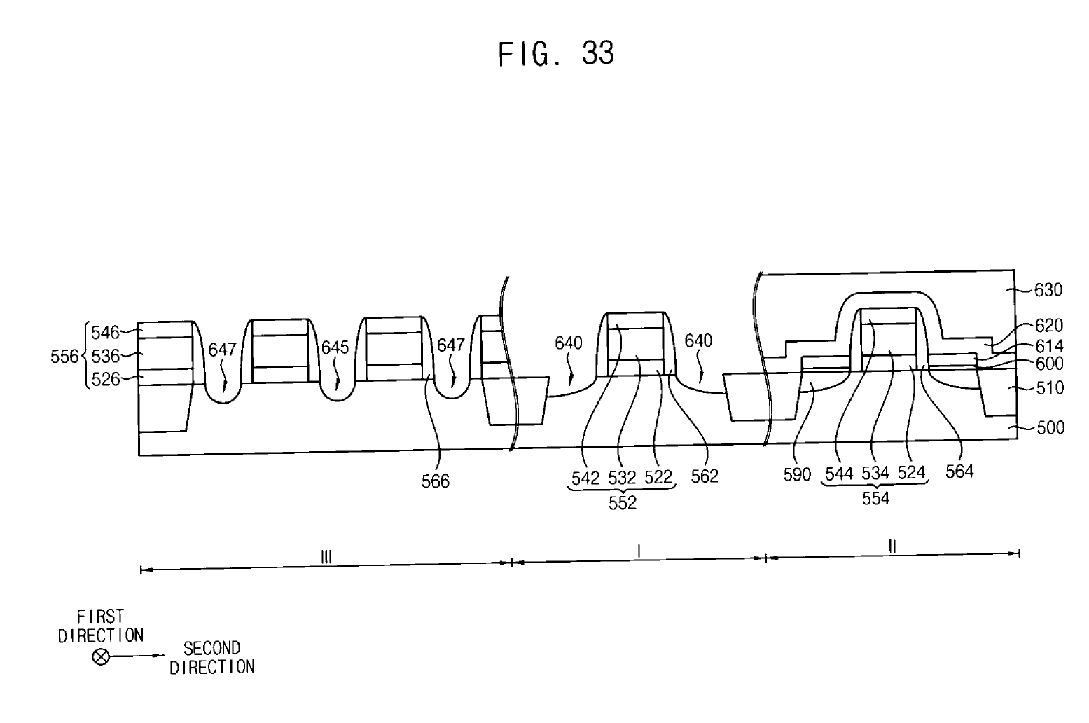

Referring to FIG. 33, a process substantially the same as or similar to that illustrated with reference to FIG. 14 may be performed.

That is, a second capping layer 620 may be formed on the second gate structure 554, the second gate spacer 564, the second silicon layer 614, the isolation layer 510 and the first capping layer 560, a second mask 630 covering the second region II may be formed, and portions of the second capping layer 620 in the first and third regions I and III and the first capping layer 560 may be etched using the second mask 630 as an etching mask to expose a top surface of the substrate 500 in the first and third regions I and III. A first gate spacer 562 may be formed on a sidewall of the first gate structure 552 in the first region I, a third gate spacer 566 may be formed on a sidewall of the third gates structure 556, and the second capping layer 620 may still remain on the substrate 500 in the second region II.

Exposed upper portions of the substrate 500 in the first and third regions I and III may be removed to form second, third and fourth recesses 640, 645 and 647. That is, an etching process using the second mask 630, the first and third gate structures 552 and 556, and the first and third gate spacers 562 and 566 as an etching mask may be performed to form the second, third and fourth recesses 640, 645 and 647. The second recess 640 may be formed in the first region I, and the third and fourth recesses 645 and 647 may be formed in the third region III.

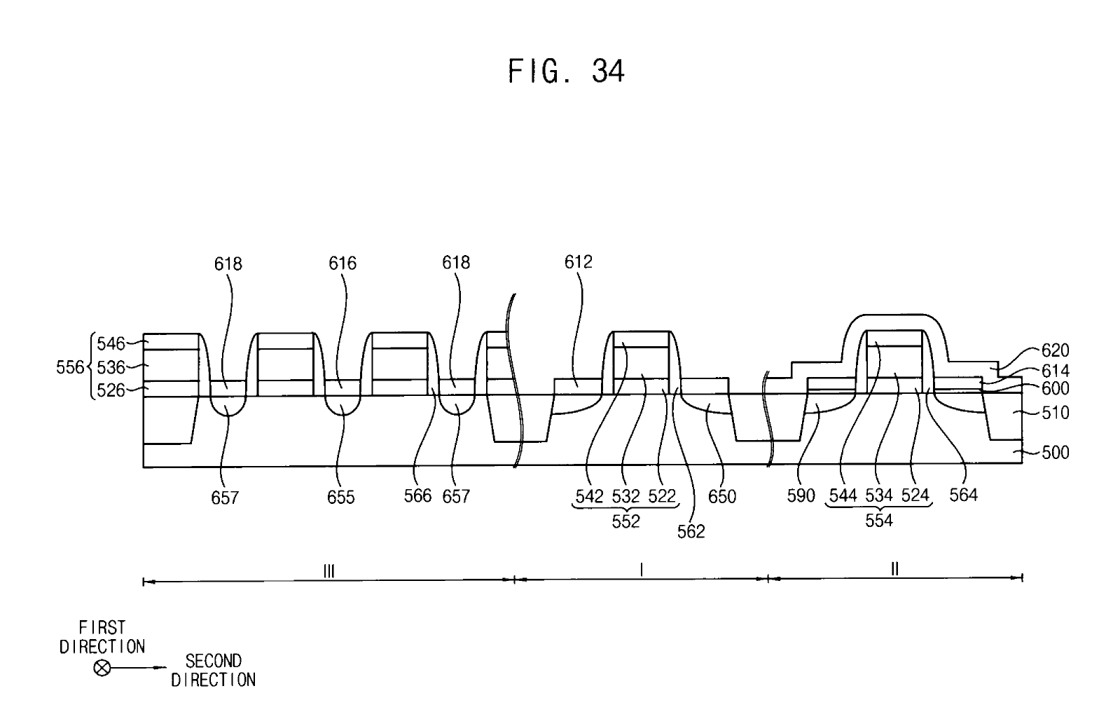

Referring to FIG. 34, a process substantially the same as or similar to that illustrated with reference to FIG. 15 may be performed.

That is, after removing the second mask 630, first, third and fourth impurity regions 650, 655 and 657 may be formed on the substrate 500 by a fourth SEG process to fill the second, third and fourth recesses 640, 645 and 647, respectively.

First, third and fourth silicon layers 612, 616 and 618 may be formed on the first, third and fourth impurity regions 650, 655 and 657, respectively, by a fifth SEG process.

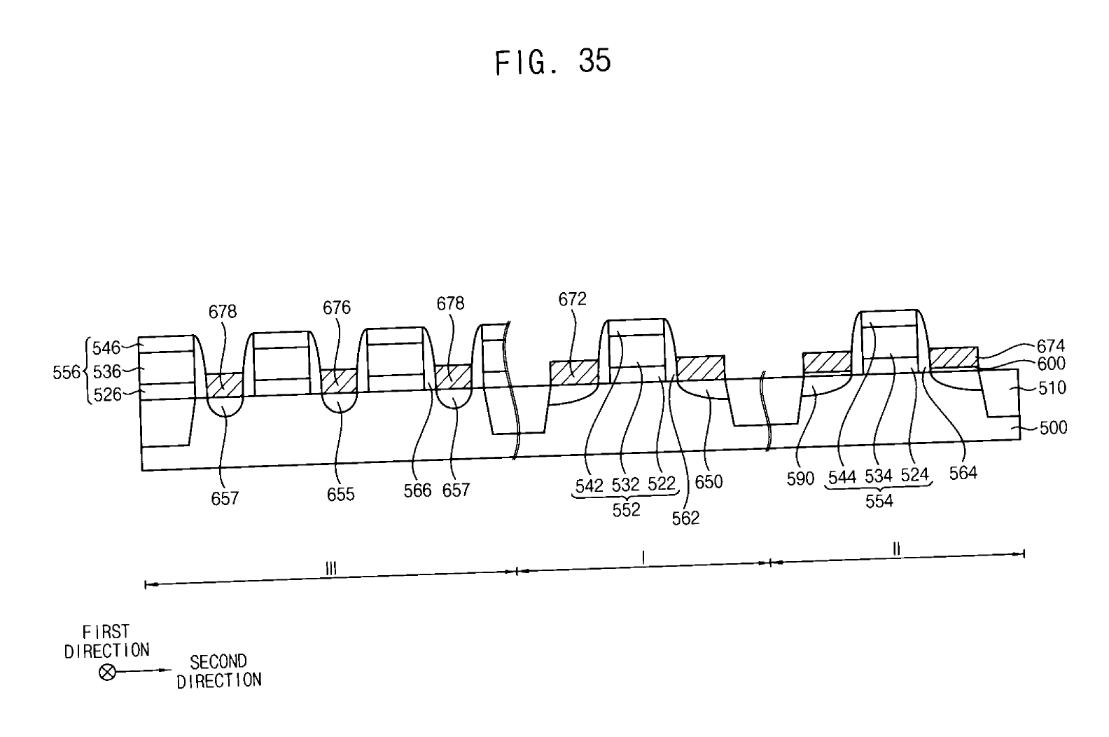

Referring to FIG. 35, processes substantially the same as or similar to those illustrated with reference to FIGS. 16 to 17 may be performed.

That is, after removing the second capping layer 620, a metal layer (not shown) may be formed on the substrate 500 having the first to third gate structures 552, 554 and 556, the first to third gate spacers 562, 564 and 566, the Fermi level pinning layer 600, the first to fourth silicon layers 612, 614, 616 and 618, and the isolation layer 510 thereon. An annealing process may be performed on the substrate 500 so that the first to fourth silicon layers 612, 614, 616 and 618 and the metal layer may be reacted with each other to form first to fourth metal silicide layers 672, 674, 676 and 678, respectively.

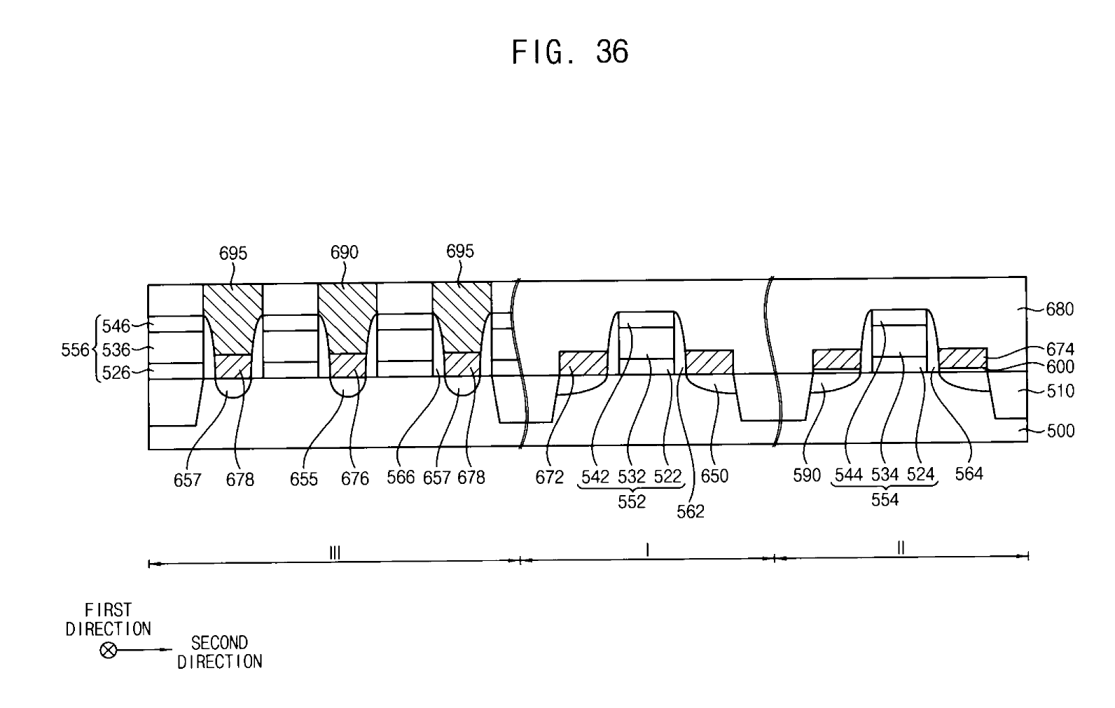

Referring to FIG. 36, a process substantially the same as or similar to that illustrated with reference to FIG. 1 may be performed.

That is, a first insulating interlayer 680 may be formed on the substrate 500 having the first to third gate structures 552, 554 and 556, the first to third gate spacers 562, 564 and 566, the first to fourth impurity regions 650, 590, 655 and 657, the Fermi level pinning layer 600, the first to fourth metal silicide layers 672, 674, 676 and 678, and the isolation layer 510, and third and fourth contact plugs 690 and 695 may be formed through the first insulating interlayer 680 to contact the third and fourth metal silicide layers 676 and 678, respectively.

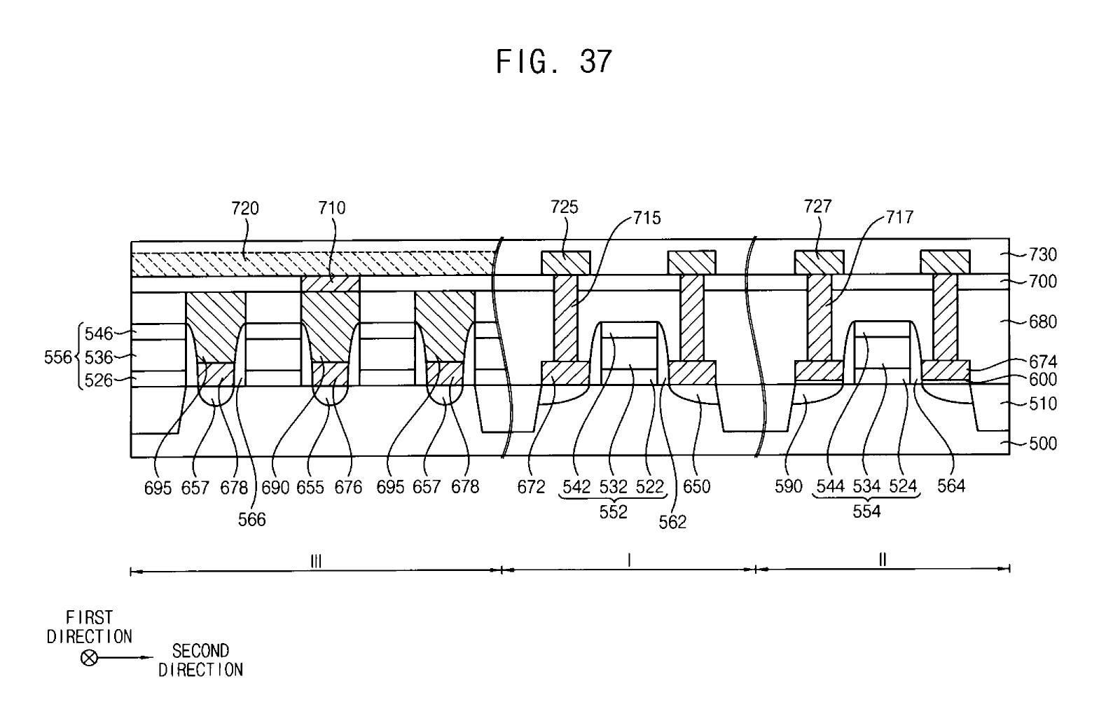

Referring to FIG. 37, a second insulating interlayer 700 may be formed on the first insulating interlayer 680 and the third and fourth contact plugs 690 and 695, a fifth contact plug 710 may be formed through the second insulating interlayer 700 to contact the third contact plug 690, and first and second contact plugs 715 and 717 may be formed through the first and second insulating interlayers 680 and 700 to contact the first and second metal silicide layers 672 and 674, respectively.

The second insulating interlayer 700 may be formed to include an insulating material, e.g., silicon oxide, and the first, second and fifth contact plugs 715, 717 and 710 may be formed to include, e.g., a metal, a metal nitride, a metal silicide, etc.

A bit line 720 contacting the fifth contact plug 710 and first and second wirings 725 and 727 contacting the first and second contact plugs 715 and 717, respectively, may be formed on the second insulating interlayer 700, and a third insulating interlayer 730 may be formed on the second insulating interlayer 700 to cover the bit line 720 and the first and second wirings 725 and 727.

The bit line 720 may be formed to include, e.g., a metal, a metal nitride, a metal silicide, etc., and the third insulating interlayer 730 may be formed to include an insulating material, e.g., silicon oxide. In another example embodiment, the bit line 720 may be formed to extend in the second direction, and a plurality of bit lines 720 may be formed in the first direction.

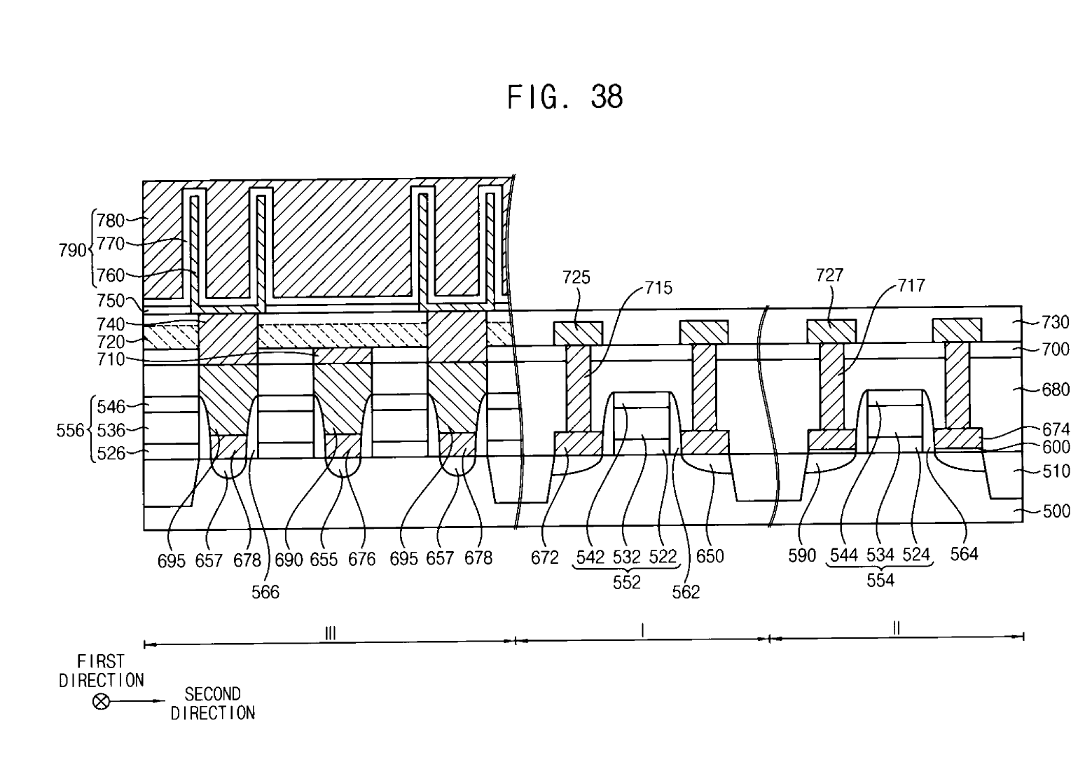

Referring to FIG. 38, a sixth contact plug 740 may be formed through the third insulating interlayer 730, and a capacitor 790 may be formed to be electrically connected to the sixth contact plug 740.

The sixth contact plug 740 may be formed to include, e.g., a metal, a metal nitride, a metal silicide, etc.

The capacitor 790 may be formed as follows.

An etch stop layer 750 and a mold layer (not shown) may be sequentially formed on the sixth contact plugs 740 and the third insulating interlayer 730, and openings (not shown) may be formed through the mold layer and the etch stop layer 750 to expose a top surface of each sixth contact plug 740. The etch stop layer 750 may be formed to include, e.g., silicon nitride, and the mold layer may be formed to include, e.g., silicon oxide. A conductive layer may be formed on sidewalls of the openings, the exposed top surface of each sixth contact plug 740 and the mold layer, and a sacrificial layer (not shown) may be formed on the conductive layer to sufficiently fill the openings. The conductive layer may be formed to include, e.g., doped polysilicon, a metal, a metal nitride, a metal silicide, etc., and the sacrificial layer may be formed to include, e.g., silicon oxide. Upper portions of the sacrificial layer and the conductive layer may be planarized until a top surface of the mold layer may be exposed, and the sacrificial layer may be removed to form a lower electrode 760 on the sidewalls of the openings and the exposed top surface of each sixth contact plug 740.

A dielectric layer 770 may be formed on the lower electrode 760 and the etch stop layer 750. The dielectric layer 770 may be formed to include, e.g., silicon oxide, silicon nitride and/or a metal oxide.

An upper electrode 780 may be formed on the dielectric layer 770. The upper electrode 780 may be formed to include, e.g., doped polysilicon, a metal, a metal nitride, a metal silicide, etc.

Thus, the capacitor 790 including the lower electrode 760, the dielectric layer 770 and the upper electrode 780 may be formed.

Referring to FIG. 29 again, a fourth insulating interlayer 800 may be formed on the third insulating interlayer 730 to cover the capacitor 790. The fourth insulating interlayer 800 may be formed to include an insulating material, e.g., silicon oxide.

Seventh and eighth contact plugs 815 and 817 may be formed through the third and fourth insulating interlayers 730 and 800 to be electrically connected to the first and second wirings 725 and 727. Third and fourth wirings 825 and 827 may be formed to be electrically connected to the seventh and eighth contact plugs 815 and 817, respectively, to manufacture the semiconductor device. The seventh and eighth contact plugs 815 and 817 and the third and fourth wirings 825 and 827 may be formed to include, e.g., a metal, a metal nitride, a metal silicide, etc.

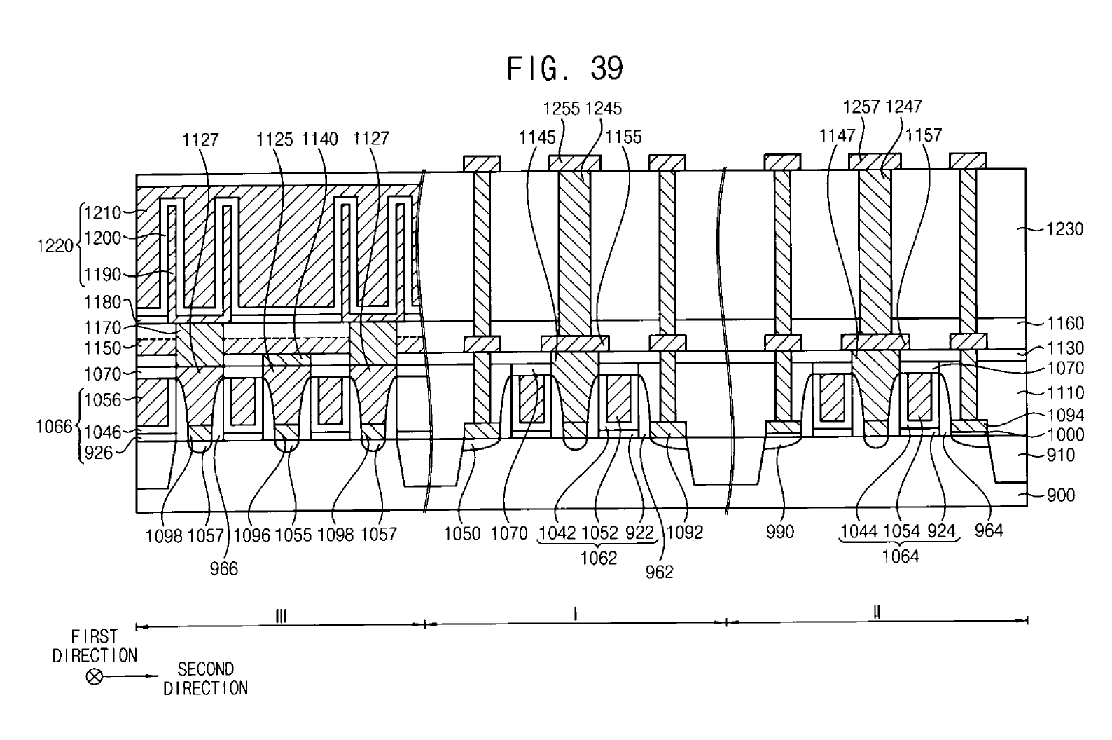

FIG. 39 is a semiconductor device in accordance with another example embodiment. This semiconductor device may be substantially the same as or similar to those of the semiconductor device illustrated with reference to FIG. 29, except for the gate structures, and thus detailed descriptions thereon are omitted herein.

Referring to FIG. 39, the semiconductor device may include a first gate structure 1062, a first impurity region 1050, a first metal silicide layer 1092 and a first contact plug 1145 on a first region I of a substrate 900, a second gate structure 1064, a second impurity region 990, a Fermi level pinning layer 1000, a second metal silicide layer 1094 and a second contact plug 1147 on a second region II of the substrate 500, and a third gate structure 1066 third and fourth impurity regions 1055 and 1057, third and fourth metal silicide layers 1096 and 1098, and third and fourth contact plugs 1125 and 1127 on a third region II of the substrate 500. The semiconductor device may further include first to third gate spacers 962, 964 and 966 on sidewalls of the first to third gate structures 1062, 1064 and 1066, respectively, first and third wirings 1155 and 1255 and a seventh contact plug 1245 on the first region I of the substrate 500, second and fourth wirings 1157 and 1257 and an eighth contact plug 1247 on the third region III of the substrate 500, and fifth and sixth contact plugs 1140 and 1170, a bit line 1150 and a capacitor 1220 on the third region III of the substrate 500. An isolation layer 910 may be formed on the substrate 900 to define an active region and a field region in the substrate 500.

The first gate structure 1062 may include a first low-k dielectric layer pattern 922, a first high-k dielectric layer pattern 1042, and a first gate electrode 1052 sequentially stacked on the substrate 900. The second gate structure 1064 may include a second low-k dielectric layer pattern 924, a second high-k dielectric layer pattern 1044, and a second gate electrode 1054 sequentially stacked on the substrate 900. The third gate structure 1066 may include a third low-k dielectric layer pattern 926, a third high-k dielectric layer pattern 1046, and a third gate electrode 1056 sequentially stacked on the substrate 900.

In another example embodiment, the first to third low-k dielectric layer patterns 922, 924 and 926 may include substantially the same material, e.g., silicon oxide, the first to third high-k dielectric layer patterns 1042, 1044 and 1046 may include substantially the same material, e.g., a metal oxide such as hafnium oxide, tantalum oxide, zirconium oxide, etc., and the first to third gate electrodes 1052, 1054 and 1056 may include substantially the same material, e.g., a metal having a relatively low resistance such as aluminum, copper, etc.

In another example embodiment, sidewalls and bottoms of the first to third gate electrodes 1052, 1054 and 1056 may be surrounded by the third to third high-k dielectric layer patterns 1042, 1044 and 1046, respectively. Alternatively, the first to third gate structures 1062, 1064 and 1066 may not include the first to third low-k dielectric layer patterns 922, 924 and 926, respectively.

The capacitor 1120 may include a lower electrode 1190, a dielectric layer 1200 and an upper electrode 1210 sequentially stacked.

The contact plugs 1145, 1147, 1125, 1127, 1140, 1170, 1245 and 1247 and the wirings 1155, 1157, 1255 and 1257 may have various other layouts that are not the same as that of FIG. 39.

The semiconductor device may include the Fermi level pinning layer 1000 between the second impurity region 990 and the second metal silicide layer 1094, and thus may have a relatively low contact resistance between the second impurity region 990 and the second contact plug 1147 even though the second metal silicide layer 1094 includes a metal having a relatively low work function because of the Fermi level pinning.

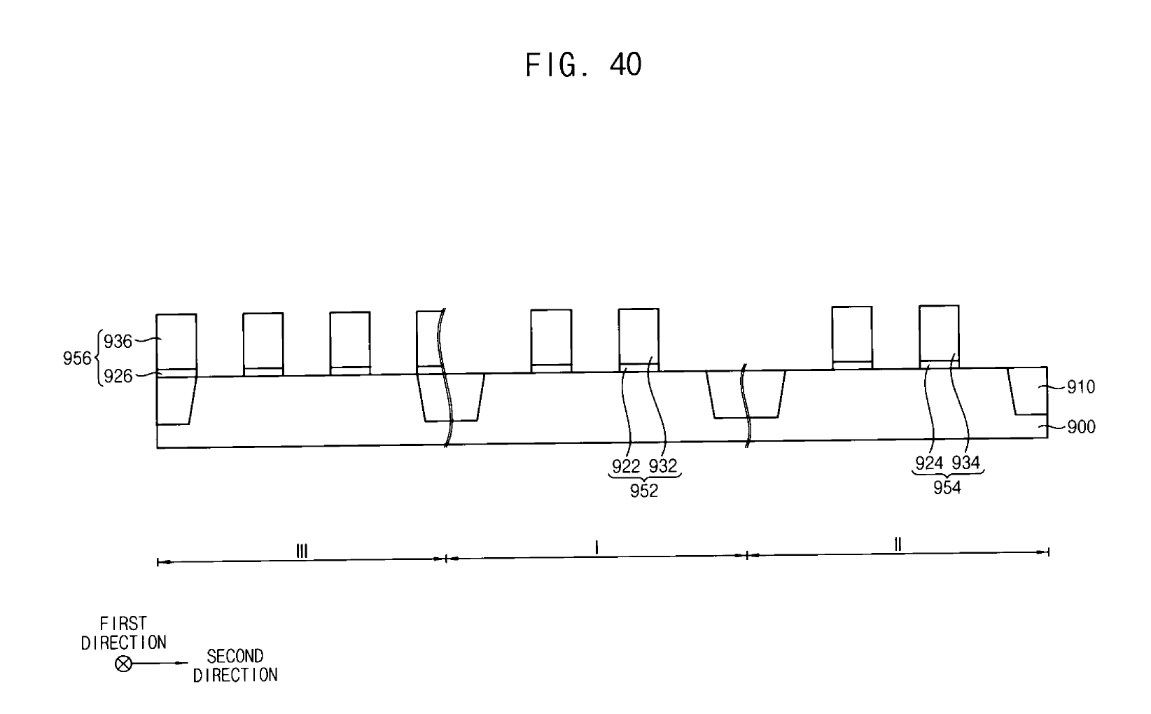

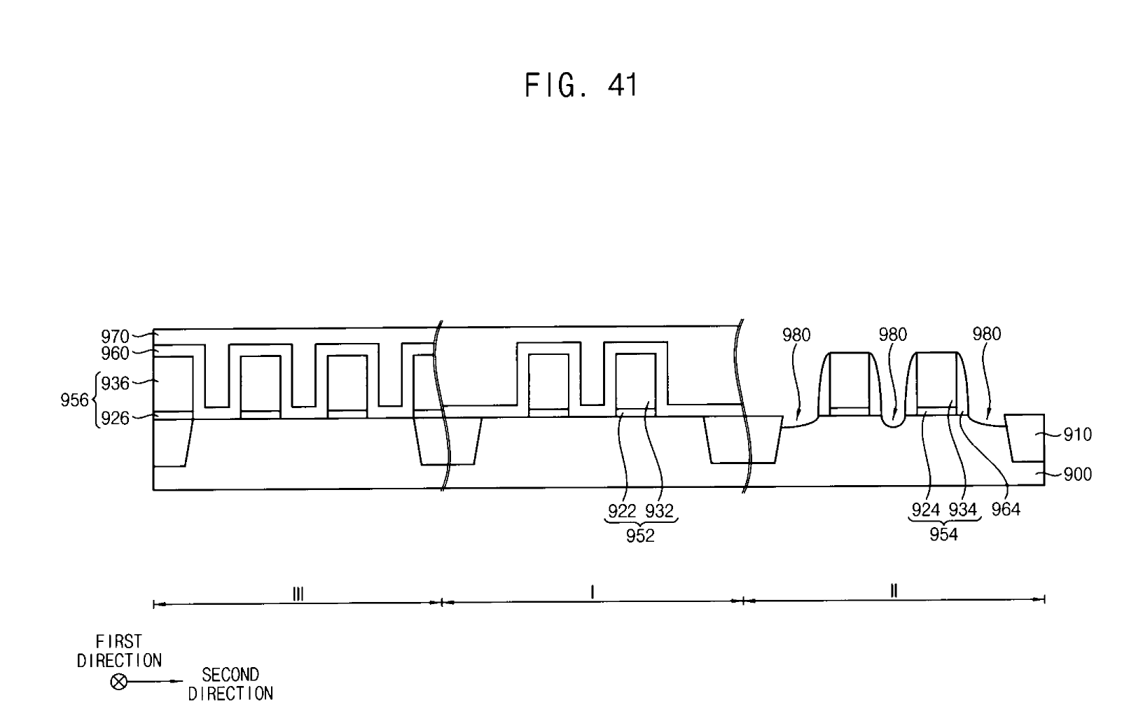

FIGS. 40 to 50 are cross-sectional views illustrating stages of a method of manufacturing a semiconductor device in accordance with another example embodiment. This method may be used in manufacturing the semiconductor device of FIG. 39, however, may not be limited thereto. Additionally, this method may include processes substantially the same as or similar to those illustrated with reference to FIGS. 30 to 38, and thus, detailed descriptions thereon are omitted herein.

Referring to FIG. 40, first to third dummy gate structures 952, 954 and 956 may be formed on first, second and third regions I, II and III, respectively, of a substrate 900 having an isolation layer 910 thereon.

The first to third dummy gate structures 952, 954 and 956 may be formed by sequentially forming a low-k dielectric layer and a dummy gate electrode layer on the substrate 900, and patterning the dummy gate electrode layer and the low-k dielectric layer through a photolithography process. Thus, the first dummy gate structure 952 may be formed to include a first low-k dielectric layer pattern 922 and a first dummy gate electrode 932 sequentially stacked on the substrate 900 in the first region I, the second dummy gate structure 954 may be formed to include a second low-k dielectric layer pattern 924 and a second dummy gate electrode 934 sequentially stacked on the substrate 900 in the second region II, and the third dummy gate structure 956 may be formed to include a third low-k dielectric layer pattern 926 and a third dummy gate electrode 936 sequentially stacked on the substrate 900 in the third region III.

In another example embodiment, the first dummy gate structure 952 may be formed to extend in a first direction substantially parallel to a top surface of the substrate 900, and a plurality of first dummy gate structures 952 may be formed in a second direction substantially parallel to the top surface of the substrate 900 and substantially perpendicular to the first direction. Each of the second and third dummy gate structure 954 and 956 may be formed to extend in the first direction, and a plurality of second dummy gate structures 954 and a plurality of third dummy gate structures 956 may be formed in the second direction likewise.

Referring to FIG. 41, a process substantially the same as or similar to that illustrated with reference to FIG. 31 may be performed.

That is, a first capping layer 960 may be formed on the substrate 900 to cover the first to third dummy gate structures 952, 954 and 956, a first mask 970 covering the first and third regions I and III may be formed on the first capping layer 960, and a portion of the first capping layer 960 in the second region II may be etched using the first mask 970 as an etching mask to expose a top surface of the substrate 900 in the second region II. In the second region II, the first capping layer 960 may remain only on a sidewall of the second gate structure 954, which may be referred to as a second gate spacer 964, and in the first and third regions I and III, the first capping layer 960 may still remain on the substrate 900. An exposed upper portion of the substrate 900 in the second region II may be removed to form a first recess 980.

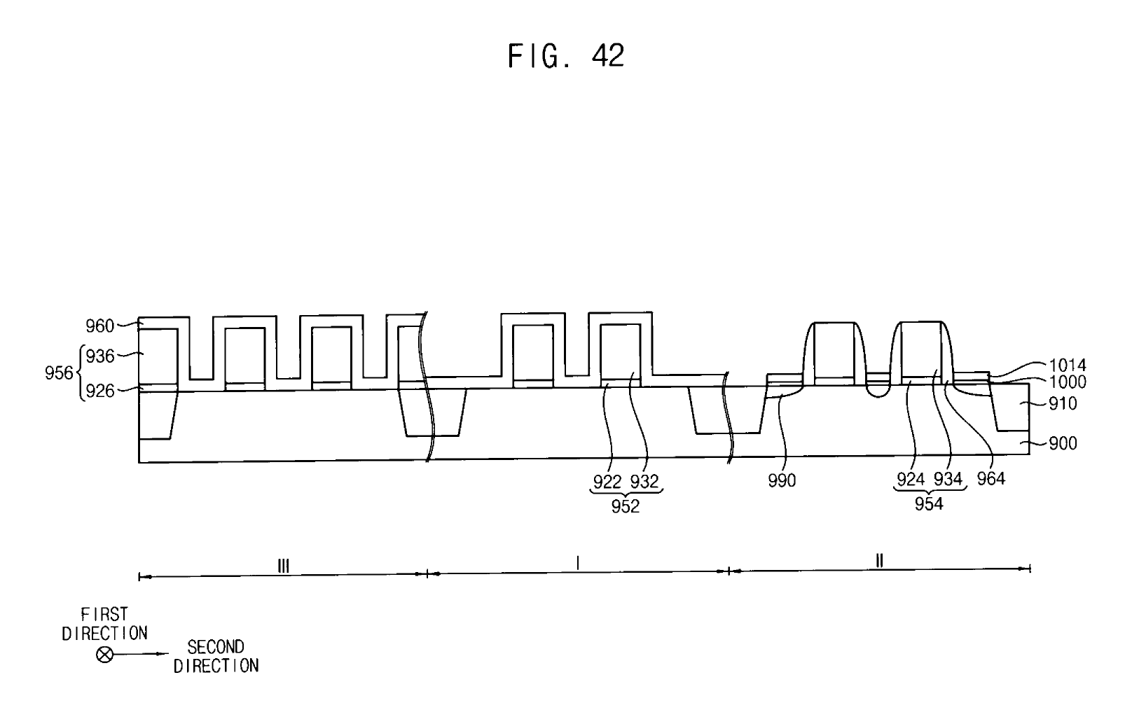

Referring to FIG. 42, a process substantially the same as or similar to that illustrated with reference to FIG. 32 may be performed.

That is, after removing the first mask 970, a second impurity region 990 may be formed on the substrate 900 by a first SEG process to fill the first recess 980, and a Fermi level pinning layer 1000 and a second silicon layer 1014 may be sequentially formed on the second impurity region 990 by second and third SEG processes, respectively.

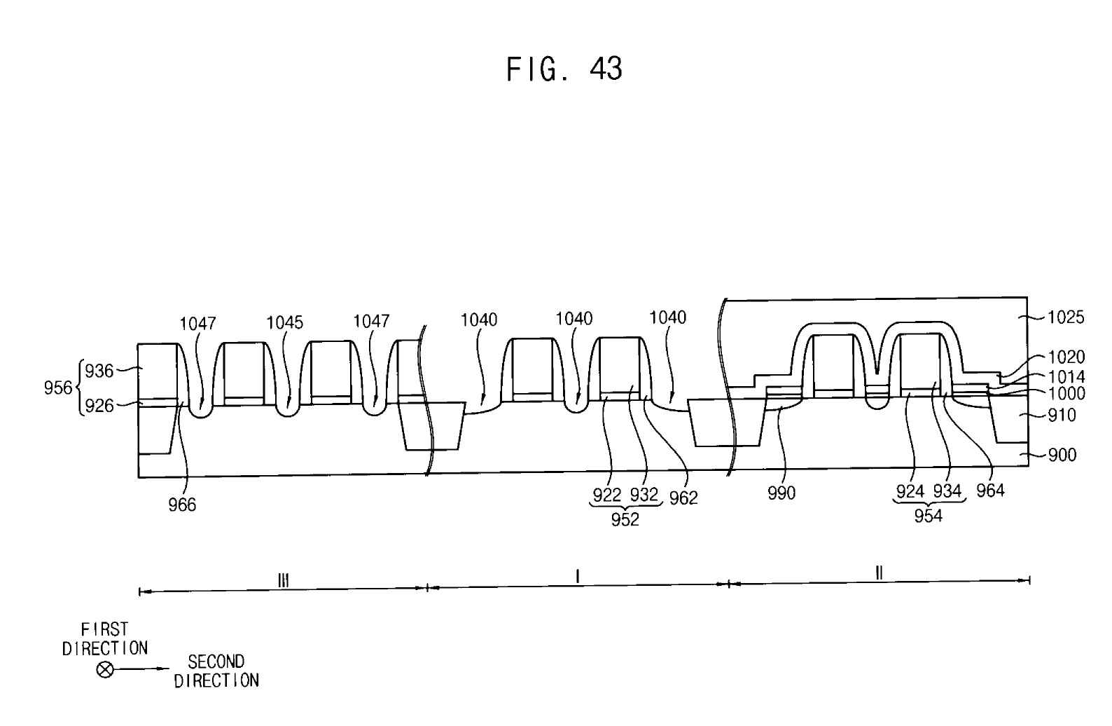

Referring to FIG. 43, a process substantially the same as or similar to that illustrated with reference to FIG. 33 may be performed.

That is, a second capping layer 1020 may be formed on the second gate structure 954, the second gate spacer 964, the second silicon layer 1014, the isolation layer 910 and the first capping layer 960, a second mask 1025 covering the second region II may be formed, and portions of the second capping layer 1020 in the first and third regions I and III and the first capping layer 960 may be etched using the second mask 1020 as an etching mask to expose a top surface of the substrate 900 in the first and third regions I and III. A first gate spacer 962 may be formed on a sidewall of the first gate structure 952 in the first region I, a third gate spacer 966 may be formed on a sidewall of the third gates structure 956, and the second capping layer 1020 may still remain on the substrate 900 in the second region II.

Exposed upper portions of the substrate 900 in the first and third regions I and III may be removed to form second, third and fourth recesses 1040, 1045 and 1047. The second recess 1040 may be formed in the first region I, and the third and fourth recesses 1045 and 1047 may be formed in the third region III.

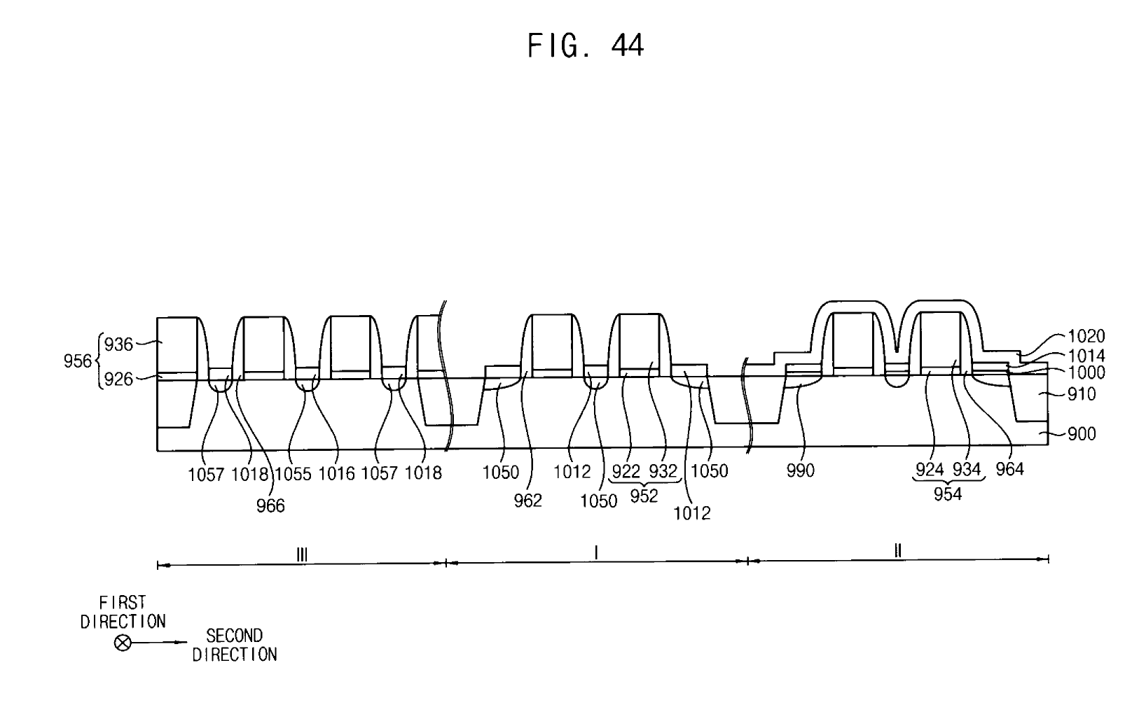

Referring to FIG. 44, a process substantially the same as or similar to that illustrated with reference to FIG. 34 may be performed.

That is, after removing the second mask 1025, first, third and fourth impurity regions 1050, 1055 and 1057 may be formed on the substrate 900 by a fourth SEG process to fill the second, third and fourth recesses 1040, 1045 and 1047, respectively.

First, third and fourth silicon layers 1012, 1016 and 1018 may be formed on the first, third and fourth impurity regions 1050, 1055 and 1057, respectively, by a fifth SEG process.

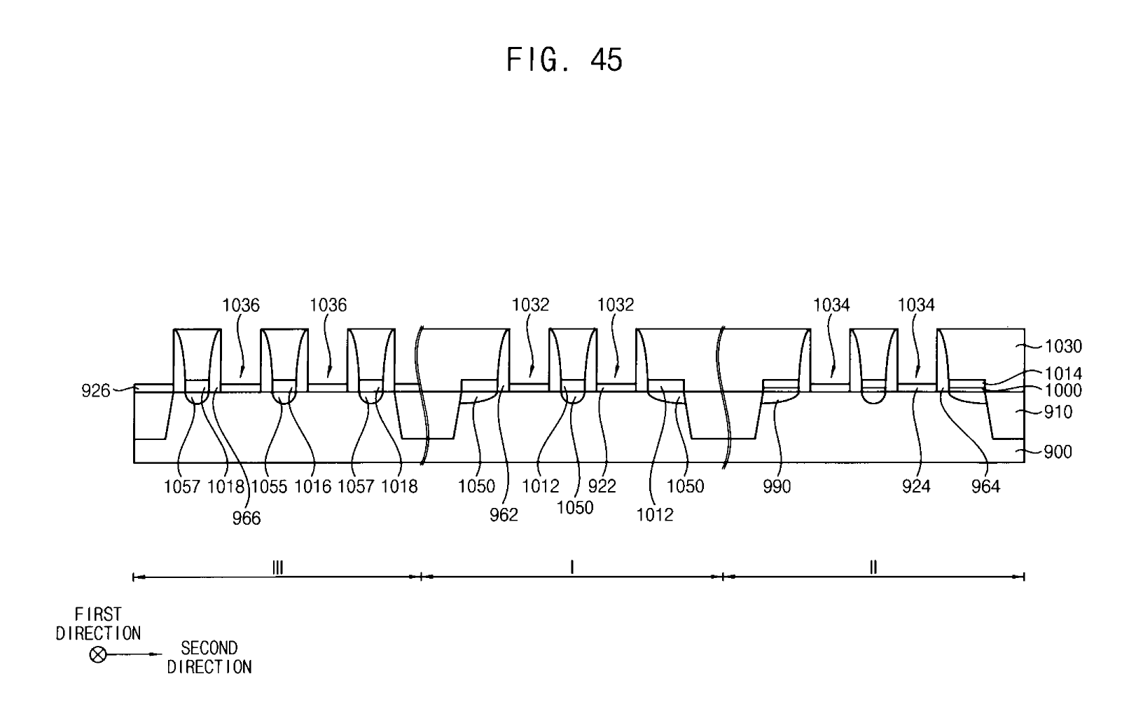

Referring to FIG. 45, after removing the second capping layer 1020 remaining in the second region II by an anisotropic etching process, an insulation layer 1030 may be formed on the substrate 900, the isolation layer 910 and the first to fourth silicon layers 1012, 1014, 1016 and 1018 to cover the first to third dummy gate structures 952, 954 and 956 and the first to third gate spacers 962, 964 and 966. The insulation layer 1030 may be formed to include, e.g., silicon oxide. An upper portion of the insulation layer 1030 may be planarized until a top surface of the first to third dummy gate structures 932, 934 and 936 may be exposed. In another example embodiment, the planarization process may be performed by a chemical mechanical polishing (CMP) process.

The exposed first to third dummy gate electrodes 932, 934 and 936 may be removed to form first to third trenches 1032, 1034 and 1036, respectively, and thus the first to third low-k dielectric layer patterns 922, 924 and 926 may be exposed. Alternatively, the first to third low-k dielectric layer patterns 922, 924 and 926 may be removed together with the first to third dummy gate structures 932, 934 and 936. The first to third dummy gate structures 932, 934 and 936 may be removed by a wet etching processor a dry etching process.

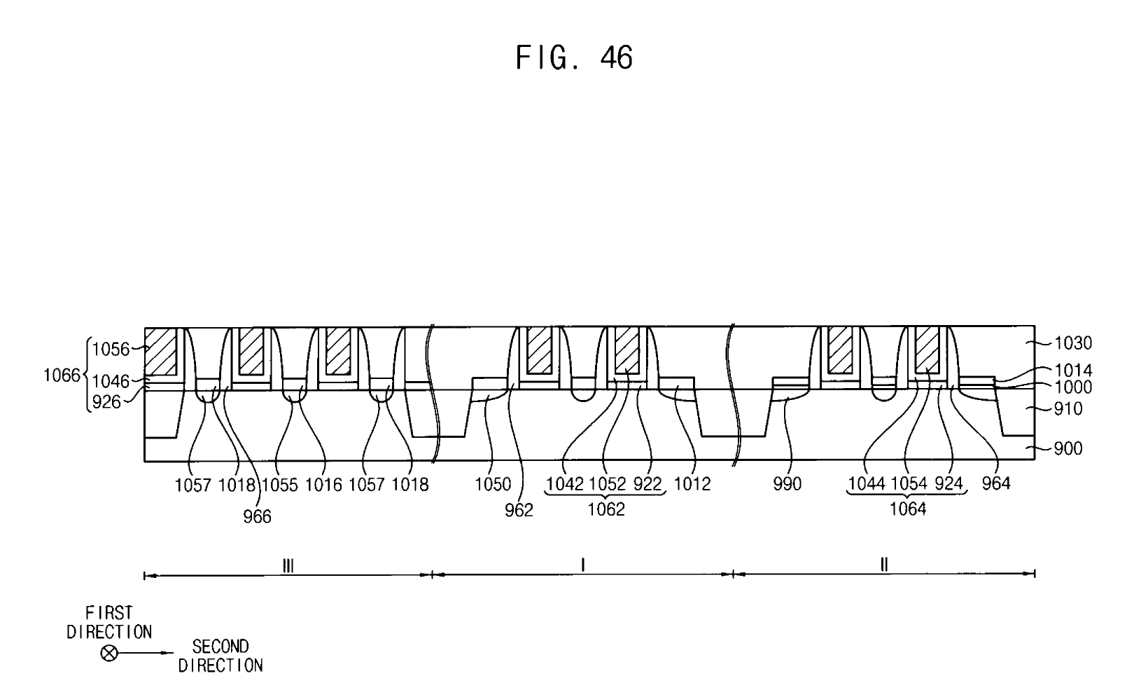

Referring to FIG. 46, first to third high-k dielectric layer patterns 1042, 1044 and 1046 may be formed on inner walls of the first to third trenches 1032, 1034 and 1036, respectively, and first to third gate electrodes 1052, 1054 and 1056 may be formed to fill remaining portions of the first to third trenches 1032, 1034 and 1036, respectively.

Particularly, a high-k dielectric layer may be formed on the inner walls of the first to third trenches 1032, 1034 and 1036 and the insulation layer 1030, and a gate electrode layer may be formed on the high-k dielectric layer to sufficiently fill remaining portions of the first to third trenches 1032, 1034 and 1036.

The high-k dielectric layer may be formed to include a metal oxide, e.g., hafnium oxide, tantalum oxide, zirconium oxide, etc., and the gate electrode layer may be formed to include a metal having a relatively low resistance, e.g., aluminum, copper, etc.

Upper portions of the gate electrode layer and the high-k dielectric layer may be planarized until a top surface of the insulation layer 1030 may be exposed, so that the first to third high-k dielectric layer patterns 1042, 1044 and 1046 may be formed on the inner walls of the first to third trenches 1032, 1034 and 1036, and the first to third gate electrodes 1052, 1054 and 1056 may be formed on the first to third high-k dielectric layer patterns 1042, 1044 and 1046 to fill the remaining portions of the first to third trenches 1032, 1034 and 1036, respectively. In another example embodiment, the planarization process may be performed by a CMP process.

Thus, a first gate structure 1062 may be formed on the first region I of the substrate 100 to include the first low-k dielectric layer pattern 922, the first high-k dielectric layer pattern 1042, and the first gate electrode 1052 sequentially stacked, and the first gate spacer 962 may be formed on the sidewall of the first gate structure 1062. The first low-k dielectric layer pattern 922 and the first high-k dielectric layer pattern 1042 may serve as a first gate insulation layer pattern of the first gate structure 1062. A second gate structure 1064 may be formed on the second region II of the substrate 900 to include the second low-k dielectric layer pattern 924 the second high-k dielectric layer pattern 1044, and the second gate electrode 1054 sequentially stacked, and the second gate spacer 964 may be formed on the sidewall of the second gate structure 1064. The second low-k dielectric layer pattern 924 and the second high-k dielectric layer pattern 1044 may serve as a second gate insulation layer pattern of the second gate structure 1064. A third gate structure 1066 may be formed on the third region III of the substrate 900 to include the third low-k dielectric layer pattern 926, the third high-k dielectric layer pattern 1046, and the third gate electrode 1056 sequentially stacked, and the third gate spacer 966 may be formed on the sidewall of the third gate structure 1066. The third low-k dielectric layer pattern 926 and the third high-k dielectric layer pattern 1046 may serve as a third gate insulation layer pattern of the third gate structure 1066.

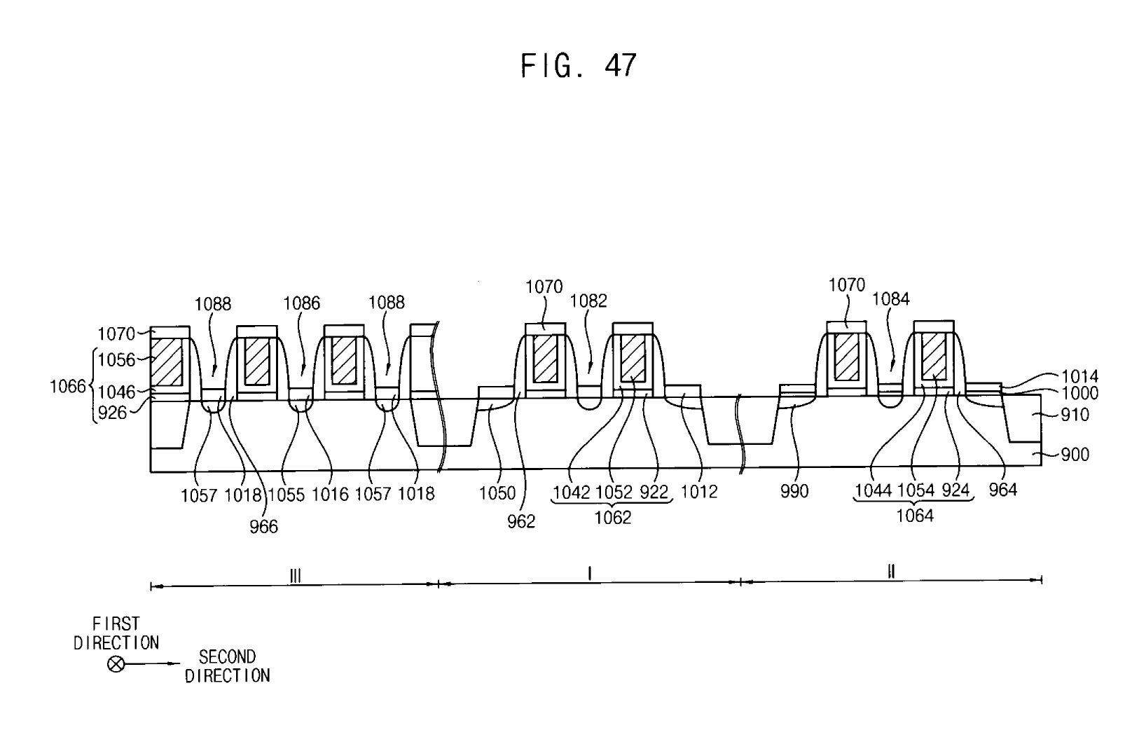

Referring to FIG. 47, a third capping layer pattern 1070 covering the gate structures 1062, 1064 and 1066 may be formed, and the insulation layer 1030 may be removed using the third capping layer pattern 1070 as an etching mask to form first to fourth openings 1082, 1084, 1086 and 1088 exposing the first to fourth silicon layers 1012, 1014, 1016 and 1018, respectively. When the openings 1082, 1084, 1086 and 1088 are formed, the isolation layer 910 may be also removed.

The third capping layer pattern 1070 may be formed by forming a third capping layer on the first to third gate structures 1062, 1064 and 1066 and the insulation layer 1030, and patterning the third capping layer by a photolithography process. In another example embodiment, the third capping layer may be formed to include a material having a high etching selectivity with respect to the insulation layer 1030, e.g., silicon nitride.

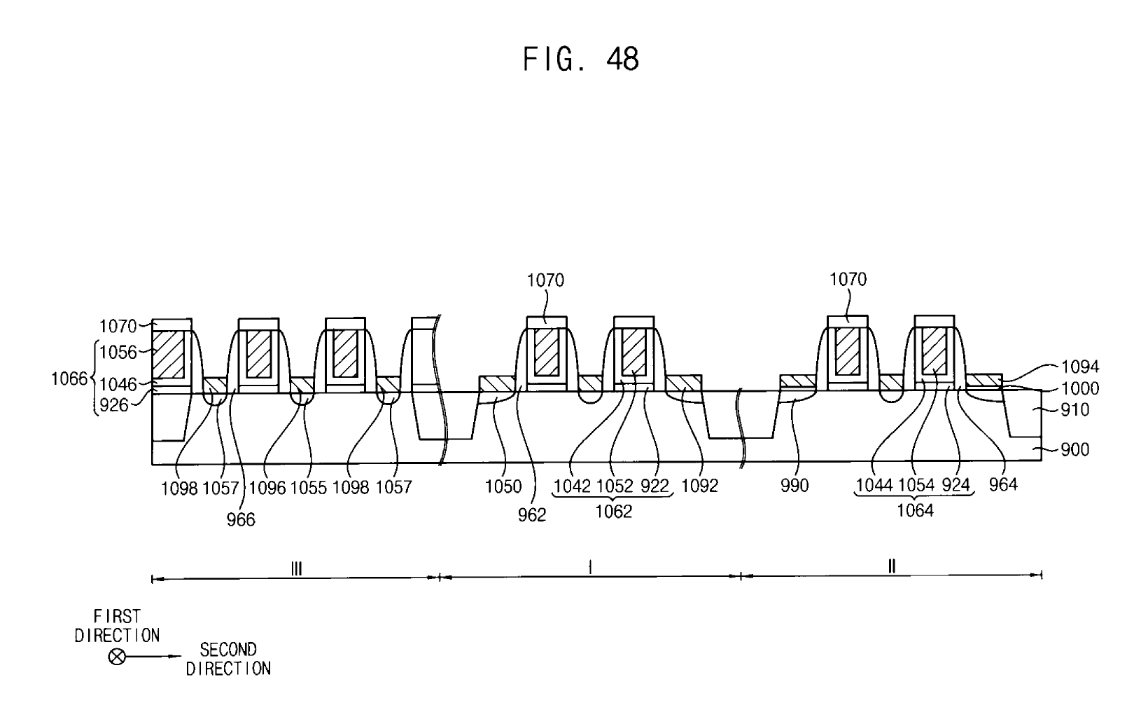

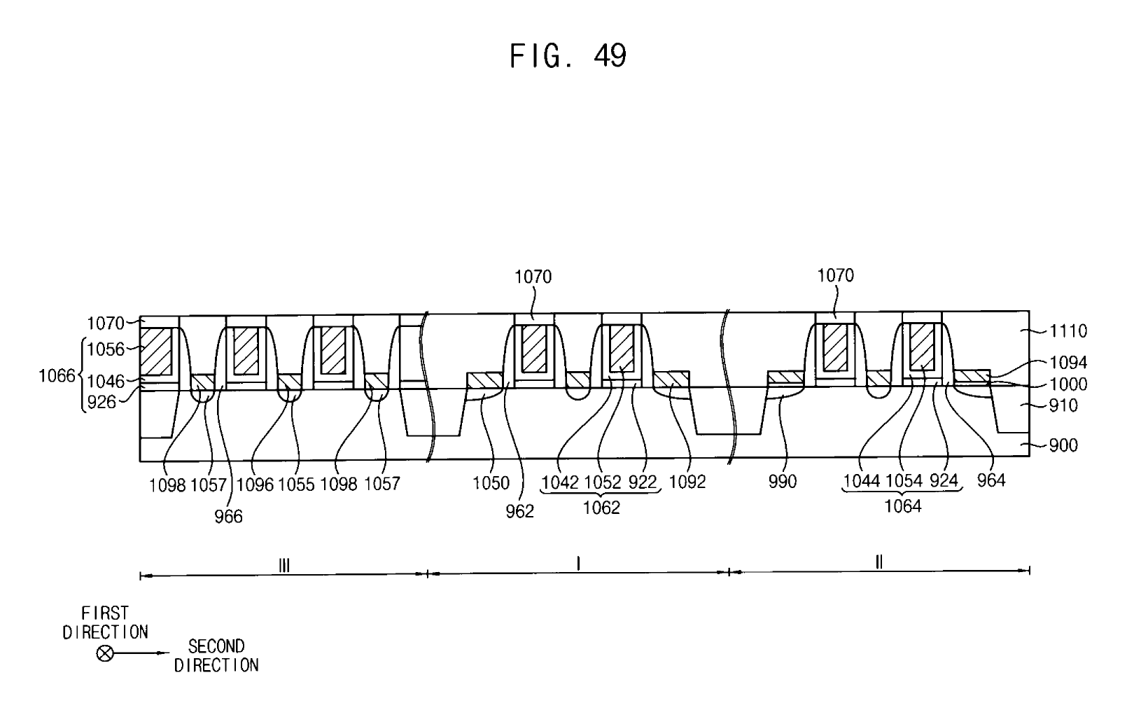

Referring to FIG. 48, a process substantially the same as or similar to that illustrated with reference to FIG. 35 may be performed.

That is, a metal layer (not shown) may be formed on the substrate 900 having the first to third gate structures 1062, 1064 and 1066, the first to third gate spacers 962, 964 and 966, the Fermi level pinning layer 1000, the first to fourth silicon layers 1012, 1014, 1016 and 1018, the first to fourth impurity regions 1050, 990, 1055 and 1057, and the isolation layer 910 thereon. An annealing process may be performed on the substrate 900 so that the first to fourth silicon layers 1012, 1014, 1016 and 1018 and the metal layer may be reacted with each other to form first to fourth metal silicide layers 1092, 1094, 1096 and 1098, respectively.

Referring to FIG. 49, a first insulating interlayer 1110 may be formed on the substrate 900 having the first to third gate structures 1062, 1064 and 1066, the first to third gate spacers 962, 964 and 966, the third capping layer pattern 1070, the Fermi level pinning layer 1000, the first to fourth metal silicide layers 1092, 1094, 1096 and 1098, the first to fourth impurity regions 1050, 990, 1055 and 1057, and the isolation layer 910 thereon, and an upper portion of the first insulating interlayer 1110 may be planarized until a top surface of the third capping layer pattern 1070 may be exposed. The first insulating interlayer 1110 may be formed to include, e.g., silicon oxide.

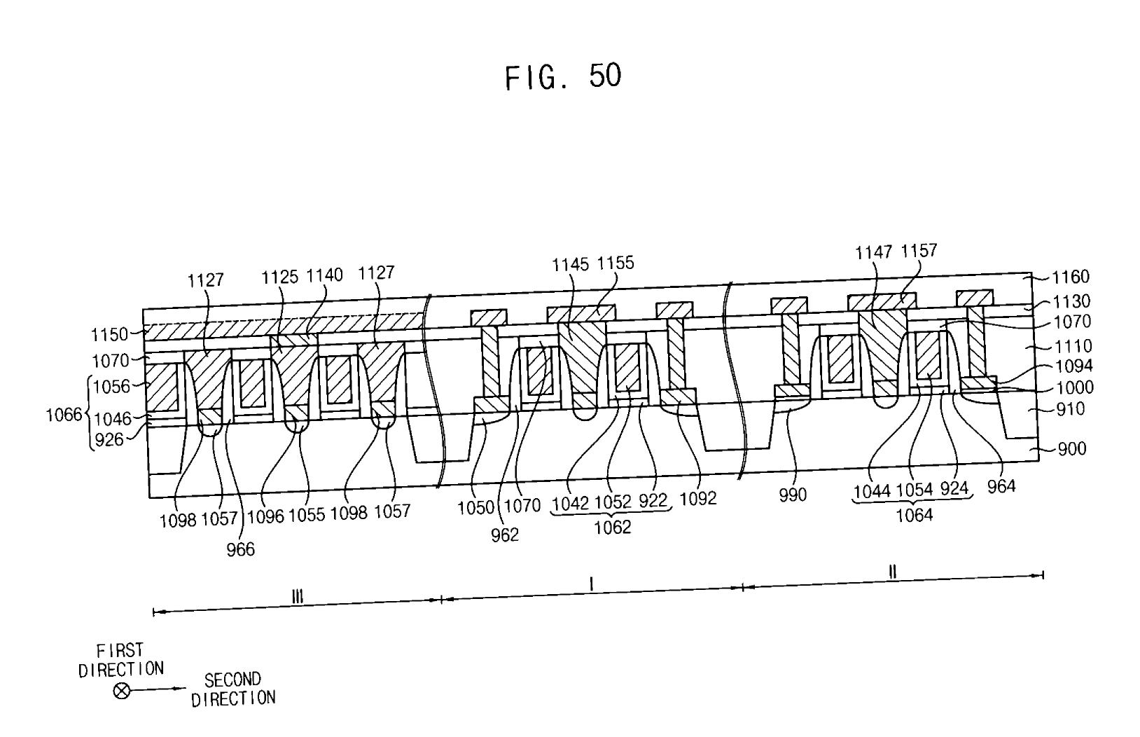

Referring to FIG. 50, processes substantially the same as or similar to those illustrated with reference to FIGS. 36 to 37 may be performed.

That is, third and fourth contact plugs 1125 and 1127 may be formed through the first insulating interlayer 1110 to contact the third and fourth metal silicide layers 1096 and 1098, respectively. A second insulating interlayer 1130 may be formed on the first insulating interlayer 1110 and the third and fourth contact plugs 1125 and 1127, a fifth contact plug 1140 may be formed through the second insulating interlayer 1130 to contact the third contact plug 1125, and first and second contact plugs 1145 and 1147 may be formed through the first and second insulating interlayers 1110 and 1130 to contact the first and second metal silicide layers 1092 and 1094, respectively.

A bit line 1150 contacting the fifth contact plug 1140 and first and second wirings 1155 and 1157 contacting the first and second contact plugs 1145 and 1147, respectively, may be formed on the second insulating interlayer 1130, and a third insulating interlayer 1160 may be formed on the second insulating interlayer 1130 to cover the bit line 1150 and the first and second wirings 1155 and 1157.

Referring to FIG. 39 again, processes substantially the same as or similar to those illustrated with reference to FIGS. 37 to 38 may be performed.

That is, a sixth contact plug 1170 may be formed through the third insulating interlayer 1160, and a capacitor 1220 may be formed to be electrically connected to the sixth contact plug 1170. The capacitor may include a lower electrode 1190, a dielectric layer 1200 and the upper electrode 1190 may be formed.

A fourth insulating interlayer 1230 may be formed on the third insulating interlayer 1160 to cover the capacitor 1220, and seventh and eighth contact plugs 1245 and 1247 may be formed through the third and fourth insulating interlayers 1160 and 1230 to be electrically connected to the first and second wirings 1155 and 1157. Third and fourth wirings 1255 and 1257 may be formed to be electrically connected to the seventh and eighth contact plugs 1245 and 1247, respectively, to manufacture the semiconductor device.

The semiconductor device and the method of manufacturing the same may be applied to various types semiconductor devices having a CMOS transistor and a semiconductor layer and a metal (silicide) layer contacting each other. For example, the present inventive concepts may be applied to not only DRAM devices but also volatile memory devices, e.g., SRAM devices, or non-volatile memory devices, e.g., flash memory devices, PRAM devices, MRAM devices, RRAM devices, etc. Particularly, the present inventive concepts may be applied to memory devices that may need a relatively low contact resistance between a substrate and a contact plug in a peripheral region or a logic region.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor device, comprising:
a first gate structure on a first region of a substrate and a second gate structure on a second region of the substrate;
a first impurity region on an upper portion of the substrate adjacent to the first gate structure and a second impurity region on an upper portion of the substrate adjacent to the second gate structure;
a first metal silicide layer on the first impurity region;
a Fermi level pinning layer on the second impurity region;
a second metal silicide layer on the Fermi level pinning layer, the Fermi level pinning layer pinning a Fermi level of the second metal silicide layer to a given energy level; and
a first contact plug on the first metal silicide layer and a second contact plug on the second metal silicide layer.

2. The semiconductor device of claim 1, wherein the first impurity region includes n-type impurities, and the second impurity region includes p-type impurities.

3. The semiconductor device of claim 2, wherein the Fermi level pinning layer pins the Fermi level of the second metal silicide layer to a level adjacent to an edge of a valence band of the Fermi level pinning layer at a surface contacting the second metal silicide layer.

4. The semiconductor device of claim 2, wherein the Fermi level pinning layer includes a germanium layer.

5. The semiconductor device of claim 2, wherein the first and second metal silicide layers include a rare earth metal.

6. The semiconductor device of claim 2, wherein the second impurity region includes a silicon-germanium layer, and the silicon-germanium layer has a germanium concentration gradient that increases from a bottom portion to a top portion thereof.

7. The semiconductor device of claim 2, wherein the second impurity region includes silicon.

8. The semiconductor device of claim 2, wherein the first impurity region includes silicon carbide.

9. The semiconductor device of claim 1, wherein the first impurity region includes p-type impurities, and the second impurity region includes n-type impurities.

10. The semiconductor device of claim 9, wherein the Fermi level pinning layer pins the Fermi level of the second metal silicide layer to a level adjacent to an edge of a conduction band of the Fermi level pinning layer at a surface contacting the second metal silicide layer.

11. The semiconductor device of claim 9, wherein the first and second metal silicide layers include a noble metal.

12. The semiconductor device of claim 1, wherein the first and second contact plugs include a metal.

13-15. (canceled)

16. A semiconductor device, comprising:
a first gate structure on a first region of a substrate and a second gate structure on a second region of the substrate;
a first impurity region adjacent to the first gate structure and a second impurity region adjacent to the second gate structure;
a first metal silicide layer on the first impurity region and a second metal silicide layer on the second impurity region, the first and second metal silicide layers including a same metal; and
a Fermi level pinning layer between the second impurity region and the second metal silicide layer, the Fermi level pinning layer pinning a Fermi level of the second metal silicide layer to a given energy level.

17. The semiconductor device of claim 16, wherein the first impurity region includes n-type impurities, and the second impurity region includes p-type impurities.

18. The semiconductor device of claim 17, wherein the Fermi level pinning layer pins a Fermi level of the second metal silicide layer to a level adjacent to an edge of a valence band of the Fermi level pinning layer at a surface contacting the second metal silicide layer.

19. The semiconductor device of claim 17, wherein the Fermi level pinning layer includes a germanium layer.

20. The semiconductor device of claim 17, wherein the first and second metal silicide layers include a rare earth metal.

21. The semiconductor device of claim 16, wherein the first impurity region includes p-type impurities, and the second impurity region includes n-type impurities.

22. The semiconductor device of claim 21, wherein the Fermi level pinning layer pins a Fermi level of the second metal silicide layer to a level adjacent to an edge of a conduction band of the Fermi level pinning layer at a surface contacting the second metal silicide layer.

23. The semiconductor device of claim 21, wherein the first and second metal silicide layers include a noble metal.
